(19) United States
(12) Patent Application Publication
(10) Pub. No.: US 2020/0388546 A1
(43) Pub. Date: Dec. 10, 2020

(54) METHOD OF MEASURING FILM THICKNESS, METHOD OF MANUFACTURING NITRIDE SEMICONDUCTOR LAMINATE AND NITRIDE SEMICONDUCTOR LAMINATE

(71) Applicants: SCIOCS COMPANY LIMITED, Hitachi-shi, Ibaraki (JP); SUMITOMO CHEMICAL COMPANY, LIMITED, Tokyo (JP)

(72) Inventor: Fumimasa HORIKIRI, Hitachi-shi (JP)

(73) Assignees: SCIOCS COMPANY LIMITED, Hitachi-shi, Ibaraki (JP); SUMITOMO CHEMICAL COMPANY, LIMITED, Tokyo (JP)

(21) Appl. No.: 16/626,427

(22) PCT Filed: Apr. 27, 2018
(86) PCT No.: PCT/JP2018/017144

§ 371 Date: Mar. 4, 2020

(30) Foreign Application Priority Data
Jun. 27, 2017 (JP) 2017-124943

(51) Int. Cl. H01L 21/66; H01L 21/02; H01L 29/20; H01L 29/872; C30B 29/40; C30B 25/20; C30B 25/16; G01B 11/06

(52) U.S. Cl. CPC H01L 22/26; H01L 21/02389; H01L 21/0254; H01L 21/02634; G01B 11/0625; H01L 29/872; C30B 29/406; C30B 25/20; C30B 25/16; H01L 29/2003

(57) ABSTRACT

There is provided a method for measuring a film thickness of a thin film in a nitride semiconductor laminate having the thin film homoepitaxially grown on a substrate comprising group-III nitride semiconductor crystal, wherein the film thickness of the thin film is measured using the substrate having a carrier concentration and an infrared absorption coefficient which are interdependent, and using Fourier Transform Infrared Spectroscopy method or Infrared Spectroscopic Ellipsometry method.

### TECHNICAL FIELD

The present disclosure relates to a method for measuring a film thickness, a method for manufacturing a nitride semiconductor laminate and a nitride semiconductor laminate.

### DESCRIPTION OF RELATED ART

Fourier Transform Infrared Spectroscopy method (FT-IR method) is known as a method for measuring noncontactly and nondestructively a film thickness for a thin film comprising a semiconductor crystal homoepitaxially grown on a substrate (for example, see patent document 1).

### PRIOR ART DOCUMENT

### Patent Document

Patent document 1: Japanese Patent Laid Open Publication No. H04-120404

### SUMMARY

### Problem to be Solved by Disclosure

However, group-III nitride semiconductor crystal typified by gallium nitride (GaN) is greatly affected by dislocation scattering. Particularly, there is no difference between absorption coefficients in an infrared region (IR) at a low carrier concentration of 1×10¹⁷ cm⁻³ or less. Therefore, in a case of a homoepitaxial film comprising crystal having the same component as the substrate, it is difficult in principle to measure a film thickness.

An object of the present disclosure is to provide a method for measuring a film thickness, enabling a measurement of a film thickness of a homoepitaxial film comprising group-III nitride semiconductor crystal using FT-IR method and the like, even in a case of a low carrier concentration of 1×10¹⁷ cm⁻³ or less for example, and is to provide a method for manufacturing a nitride semiconductor laminate and a nitride semiconductor laminate.

### Means for Solving the Problem

According to an aspect of the present disclosure, there is provided a method for measuring a film thickness of a thin film in a nitride semiconductor laminate having the thin film homoepitaxially grown on a substrate comprising group-III nitride semiconductor crystal,

wherein the film thickness of the thin film is measured

using the substrate having a carrier concentration and an infrared absorption coefficient which are interdependent, and

using Fourier Transform Infrared Spectroscopy method or Infrared Spectroscopic Ellipsometry method.

### Advantage of the Disclosure

According to the present disclosure, a film thickness of the homoepitaxial film comprising group-III nitride semiconductor crystal can be measured using FT-IR method and the like, even in a case of a low carrier concentration of 1×10¹⁷ cm⁻³ or less for example, because difference in an IR absorption coefficient occurs depending on a carrier concentration.

### BRIEF DESCRIPTION OF THE DRAWINGS

FIG. 1 is a cross-sectional view illustrating schematically a schematic constitution example of a nitride semiconductor laminate 1 according to an embodiment of the present disclosure.

FIG. 2A and FIG. 2B are views illustrating constitution examples of a substrate 10 in the nitride semiconductor laminate according to an embodiment of the present disclosure, wherein FIG. 2A is a schematic plan view and FIG. 2B is a schematic cross-sectional view.

FIG. 3 is a view illustrating Wien's displacement law.

FIG. 4 is a view illustrating free electron concentration interdependence of an absorption coefficient measured at room temperature (27° C.) in GaN crystal manufactured by a manufacturing method according to an embodiment of the present disclosure.

FIG. 5 is a view illustrating an intrinsic carrier concentration with respect to a temperature of GaN crystal.

FIG. 6A is a view illustrating a relationship between an absorption coefficient at a wavelength of 2 μm and the free electron concentration in GaN crystal manufactured by the manufacturing method according to an embodiment of the present disclosure, and FIG. 6B is a view comparing the relationship between the absorption coefficient at a wavelength of 2 μm and the free electron concentration.

FIG. 7 is a flowchart illustrating a schematic procedure of a method for manufacturing the nitride semiconductor laminate 1 according to an embodiment of the present disclosure.

FIG. 8 is a schematic constitution view of a vapor phase growth apparatus 200.

FIG. 9A is a view illustrating how GaN crystal film 6 is grown thickly on a seed crystal substrate 5, and FIG. 9B is a view illustrating how a plurality of nitride crystal substrates 10 are obtained by slicing a thickly grown GaN crystal film 6.

FIG. 10A is a schematic top view illustrating a holding member 300 on which the nitride crystal substrate 10 or the semiconductor laminate 1 is placed, and FIG. 10B is a schematic front view illustrating the holding member 300 on which the nitride crystal substrate 10 or the semiconductor laminate 1 is placed.

FIG. 11 is a flowchart illustrating an example of a procedure of a method for measuring a film thickness according to an embodiment of the present disclosure.

FIG. 12A is a schematic view illustrating an example of an optical model of a multilayer film, and FIG. 12B is a schematic view illustrating an example of an optical model simplifying FIG. 12A.

FIG. 13A and FIG. 13B are explanatory views illustrating specific examples of calculation results for refractive index n and extinction coefficient k according to Drude model, wherein FIG. 13 A is a view illustrating a calculation result for an epi-layer and FIG. 13B is a view illustrating a calculation result for a substrate.

FIG. 14A and FIG. 14B are explanatory views illustrating specific examples of calculation results for refractive index n and extinction coefficient k according to Lorentz-Drude model, wherein FIG. 14 A is a view illustrating a calculation result for an epi-layer and FIG. 14B is a view illustrating a calculation result for a substrate.

FIG. 15A and FIG. 15B are explanatory views illustrating specific examples of calculation results for reflection spectrum in a case of vertical incidence (θi=0°), wherein FIG. 15A is a view illustrating a reflection spectrum regarding Drude model and FIG. 15B is a view illustrating a reflection spectrum regarding Lorentz-Drude model.

FIG. 16A and FIG. 16B are explanatory views illustrating specific examples of calculation results for reflection spectrum in a case of non-vertical incidence (θi=30°), wherein FIG. 16A is a view illustrating a reflection spectrum regarding Drude model and FIG. 16 B is a view illustrating a reflection spectrum regarding Lorentz-Drude model.

FIG. 17 is a schematic constitution view of an FT-IR measurement apparatus 50.

### DETAILED DESCRIPTION OF THE DISCLOSURE

### An Embodiment of the Present Disclosure

An embodiment of the present disclosure will be described hereafter, with reference to the drawings.

### (1) Constitution of a Nitride Semiconductor Laminate 1

First, a constitution example of a nitride semiconductor laminate 1 according to the present embodiment will be described.

The nitride semiconductor laminate 1 described in the present embodiment is, for example, a substrate-shaped structure used as a base body when manufacturing a semiconductor device such as Schottky barrier diode (SBD). The nitride semiconductor laminate 1 is also referred to as “an intermediate body” or “an intermediate precursor” hereafter, because it is used as the base body of the semiconductor device.

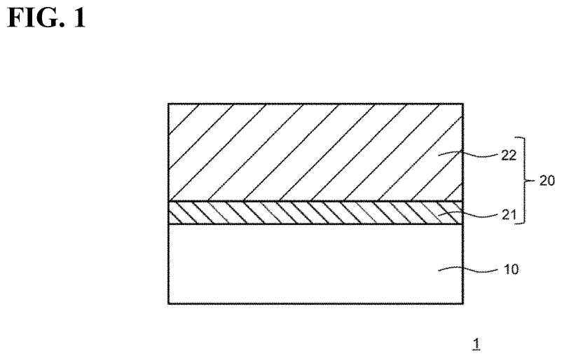

As illustrated in FIG. 1, the nitride semiconductor laminate (intermediate body) 1 according to the present embodiment is constituted including at least a substrate 10, and a semiconductor layer 20 which is a thin film formed on the substrate 10.

### (1-i) Detailed Constitution of the Substrate 10

Next, the substrate 10 constituting the nitride semiconductor laminate (intermediate body) 1 will be described in detail. In the following, a main surface of a substrate or the like refers to mainly an upper main surface of the substrate or the like, and may also be referred to as a surface of the substrate or the like. A back surface of the substrate or the like refers to mainly a lower main surface of the substrate or the like.

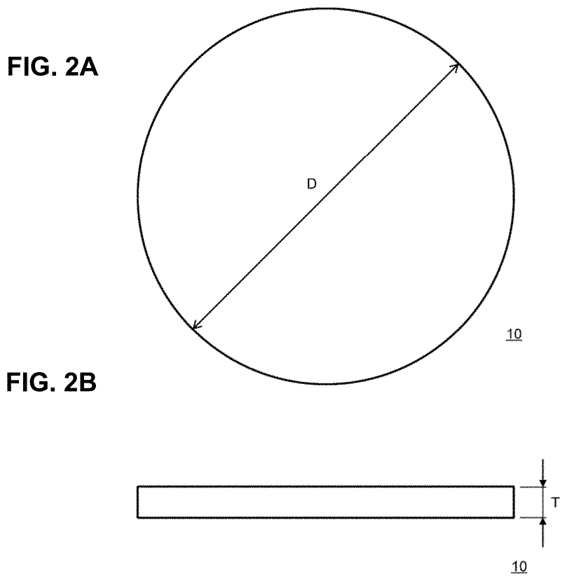

As illustrated in FIG. 2, the substrate 10 is formed into a disc-like shape, and comprises single crystal of group-III nitride semiconductor, specifically comprises, for example, single crystal of gallium nitride (GaN).

A plane orientation of a main surface of the substrate 10 is, for example, a (0001) plane (+c plane, Ga-polar plane). However, for example, it may be 000-1 plane (−c plane, N-polar plane).

GaN crystal constituting the substrate 10 may have a predetermined off-angle with respect to the main surface of the substrate 10. The off-angle refers to an angle between a normal direction of the main surface of the substrate 10 and a main axis (c-axis) of GaN crystal constituting the substrate 10. Specifically, the off-angle of the substrate 10 is, for example, 0° or more and 1.2° or less. It is also conceivable that the off-angle is larger than these angles and is 2° or more and 4° or less. Further, for example, a so-called double off having the off-angle in each of a-direction and in-direction may be acceptable.

Further, a dislocation density on the main surface of the substrate 10 is, for example, 5×10⁶ numbers/cm² or less. When the dislocation density on the main surface of the substrate 10 is more than 5×10⁶ numbers/cm², a breakdown voltage may be locally reduced in the later-described semiconductor layer 20 formed on the substrate 10. In contrast, according to the present embodiment, since the dislocation density on the main surface of the substrate 10 is 5×10⁶ numbers/cm² or less, reduction of the local breakdown voltage can be suppressed in the semiconductor layer 20 formed on the substrate 10.

The main surface of the substrate 10 is an epi-ready surface, and a surface roughness (arithmetic mean roughness Ra) on the main surface of the substrate 10 is, for example, 10 nm or less, preferably 5 nm or less.

Further, although a diameter D of the substrate 10 is not particularly limited, the diameter D is, for example, 25 mm or more. When the diameter D of the substrate 10 is less than 25 mm, productivity at the time of manufacturing a semiconductor device using the substrate 10 is likely to be reduced. Therefore, the diameter D of the substrate 10 is preferably 25 mm or more. Further, a thickness T of the substrate 10 is, for example, 150 μm or more and 2 mm or less. When the thickness T of the substrate 10 is less than 150 μm, a mechanical strength of the substrate 10 may be reduced, which may make it difficult to maintain a freestanding state. Therefore, the thickness T of the substrate 10 is preferably 150 μm or more. Here, for example, the diameter D of the substrate 10 is 2 inches, and the thickness T of the substrate 10 is 400 μm.

Further, the substrate 10 contains, for example, n-type impurities (donor). Examples of the n-type impurities contained in the substrate 10 include silicon (Si) and germanium (Ge). Further, examples of the n-type impurities include oxygen (O), O and Si, O and Ge, O and Si and Ge, etc., in addition to Si and Ge. Since the substrate 10 is doped with the n-type impurities, free electrons having a predetermined concentration are generated in the substrate 10.

### (Regarding Absorption Coefficient and the Like)

In the present embodiment, the substrate 10 satisfies predetermined requirements for the absorption coefficient in an infrared region (infrared absorption coefficient). Thereby, the substrate 10 has a carrier concentration and the infrared absorption coefficient which are interdependent (which are dependent each other), as described later in detail.

Details will be described hereafter.

When manufacturing the nitride semiconductor laminate 1 or when manufacturing a semiconductor device using the nitride semiconductor laminate 1, for example, as described later, a step of heating the substrate 10 is performed, such as a step of epitaxially growing the semiconductor layer 20 on the substrate 10, a step of activating impurities in the semiconductor layer 20, and the like. For example, when the substrate 10 is heated by irradiating the substrate 10 with the infrared rays, it is important to set a heating condition based on the absorption coefficient of the substrate 10.

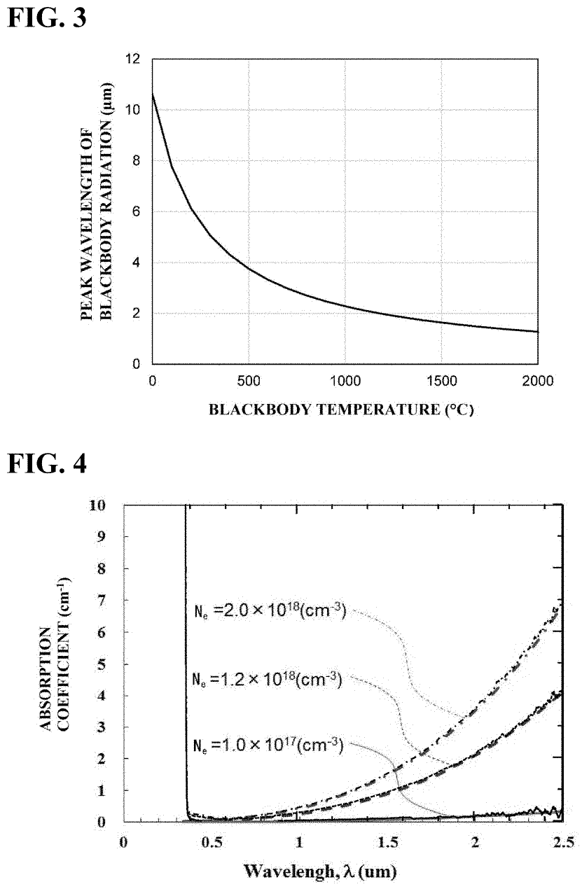

Here, FIG. 3 is a view illustrating Wien's displacement law. In FIG. 3, a horizontal axis indicates a blackbody temperature (° C.), and a vertical axis indicates a peak wavelength (μm) of blackbody radiation. According to Wien's displacement law illustrated in FIG. 3, the peak wavelength of the blackbody radiation is inversely proportional to the blackbody temperature. The peak wavelength and the temperature have a relationship of λ=2896/(T+273). Here, the peak wavelength is λ (μm) and the temperature is T (° C.). If radiation from a predetermined heating source in the step of heating the substrate 10 is assumed to be the blackbody radiation, the substrate 10 is irradiated with the infrared rays having a peak wavelength corresponding to the heating temperature from the heating source. For example, when the temperature is about 1200° C., the peak wavelength λ of the infrared rays is 2 and when the temperature is about 600° C., the peak wavelength λ of the infrared rays is 3.3 μm.

When the substrate 10 is irradiated with the infrared rays having such a wavelength, an absorption by the free electrons (free carrier absorption) occurs in the substrate 10. Thus, the substrate 10 is heated.

Therefore, in the present embodiment, the infrared absorption coefficient of the substrate 10 satisfies the following predetermined requirements based on the free carrier absorption of the substrate 10.

FIG. 4 is a view illustrating a free electron concentration interdependence of an absorption coefficient measured at room temperature (27° C.) in GaN crystal manufactured by a manufacturing method according to the present embodiment. FIG. 4 illustrates measurement results of a substrate comprising GaN crystal manufactured by doping with Si by the later-described manufacturing method. In FIG. 4, a horizontal axis indicates a wavelength (μm), and a vertical axis indicates an absorption coefficient α (cm⁻¹) of GaN crystal. Further, the absorption coefficients α of GaN crystal are plotted for each predetermined free electron concentration Nₑ. Here, the free electron concentration in GaN crystal is Nₑ. As illustrated in FIG. 4, in GaN crystal manufactured by the later-described manufacturing method, the absorption coefficient α of GaN crystal tends to increase (monotonously increase) toward a long wavelength, due to the free carrier absorption in a wavelength range of at least 1 μm or more and 3.3 or less. Further, the free carrier absorption tends to increase in GaN crystal as the free electron concentration Nₑ in GaN crystal increases.

Since the substrate 10 of the present embodiment comprises GaN crystal manufactured by the later-described manufacturing method, the substrate 10 is in a state where crystal strain is small and almost no impurities other than oxygen (O) and the n-type impurities (for example, impurities, etc., for compensating the n-type impurities) are contained. Thereby, a free electron concentration interdependence of the absorption coefficient like the above FIG. 4 is shown. As a result, in the substrate 10 of the present embodiment, the infrared absorption coefficient can be approximately expressed as a function of the free carrier concentration and the wavelength as follows.

Specifically, in the substrate 10 of the present embodiment, the absorption coefficient α in the wavelength range of at least 1 μm or more and 3.3 μm or less (preferably 1 μm or more and 2.5 μm or less) is approximately expressed by the following equation (1).

α=NₑKλ^{a} (1)

(wherein, the wavelength is λ (μm), the absorption coefficient of the substrate 10 at 27° C. is α (cm⁻¹), the free electron concentration in the substrate 10 is Nₑ (cm⁻³), and K and a are constants, satisfying 1.5×10⁻¹⁹≤K≤6.0×10⁻¹⁹, a=3)

“The absorption coefficient α is approximately expressed by equation (1)” means that the absorption coefficient α is approximately expressed by equation (1) by a least-squares method. That is, the above definition includes not only a case where the absorption coefficient completely matches equation (1) (i.e., equation (1) is satisfied) but also a case where equation (1) is satisfied within a predetermined error range. The predetermined error is, for example, within ±0.1α, preferably within ±0.01α at a wavelength of 2 μm.

The absorption coefficient α in the above wavelength range may be considered to satisfy the following equation (1)′.

1.5×10⁻¹⁹Nₑλ³≤α≤6.0×10⁻¹⁹Nₑλ³ (1)′

Further, among the substrates 10 which satisfy the above definition, particularly, in a substrate of very high purity (that is, low impurity concentration) where crystal strain is extremely small, the absorption coefficient α in the above wavelength range is approximately expressed by the following equation (1)″ (i.e., equation (1)″ is satisfied).

α=2.2×10⁻¹⁹Nₑλ³ (1)″

Similarly to the above-described definition, the definition that “the absorption coefficient α is approximately expressed by equation (1)′” includes not only a case where the absorption coefficient completely matches equation (1)′ (i.e., equation (1)′ is satisfied) but also a case where equation (1)′ is satisfied within a predetermined error range. The predetermined error is, for example, within ±0.1α, preferably within ±0.01α at a wavelength of 2 μm.

In the above-described FIG. 4, actual measured values of the absorption coefficient α of GaN crystal manufactured by the later-described manufacturing method are indicated by a thin line. Specifically, the actual measured value of the absorption coefficient α is indicated by a thin solid line when the free electron concentration Nₑ is 1.0×10¹⁷ cm⁻³, the actual measured value of the absorption coefficient α is indicated by a thin dotted line when the free electron concentration Nₑ is 1.2×10¹⁸ cm⁻³, and the actual measured value of the absorption coefficient α is indicated by a thin one dot chain line when the free electron concentration Nₑ is 2.0×10¹⁸ cm⁻³. On the other hand, in the above-described FIG. 4, functions of the above equation (1) are indicated by a thick line. Specifically, the function of equation (1) is indicated by a thick solid line when the free electron concentration Nₑ is 1.0×10¹⁷ cm⁻³, the function of equation (1) is indicated by a thick dotted line when the free electron concentration Nₑ is 1.2×10¹⁸ cm⁻³, and the function of equation (1) is indicated by a thick one dot chain line when the free electron concentration Nₑ is 2.0×10¹⁸ cm⁻³. As illustrated in FIG. 4, the actual measured values of the absorption coefficient α of GaN crystal manufactured by the later-described manufacturing method can be fitted with high accuracy by the function of equation (1). In a case of FIG. 4 (in a case of Si-doping), the absorption coefficient α is approximately expressed with high accuracy by equation (1) when K=2.2×10⁻¹⁹.

Thus, since the absorption coefficient of the substrate 10 is approximately expressed by equation (1), the absorption coefficient of the substrate 10 can be designed with high accuracy based on the concentration Nₑ of the free electrons in the substrate 10.

Further, in the present embodiment, for example, the absorption coefficient α of the substrate 10 satisfies the following equation (2) in the wavelength range of at least 1 μm or more and 3.3 μm or less.

0.15λ³≤α≤6λ³ (2)

In a case of α<0.15λ³, the infrared rays cannot be sufficiently absorbed in the substrate 10, and heating of the substrate 10 may become unstable. In contrast, in a case of 0.15λ³≤α, the infrared rays can be sufficiently absorbed in the substrate 10, and the substrate 10 can be stably heated. On the other hand, in a case of 6λ³<α, this case corresponds to a case where the concentration of the n-type impurities in the substrate 10 is more than a predetermined value (more than 1×10¹⁹ at·cm⁻³) as described later, and crystallinity of the substrate 10 may be reduced. In contrast, in a case of α≤6λ³, this case corresponds to a case where the concentration of the n-type impurities in the substrate 10 is a predetermined value or less, and good crystallinity of the substrate 10 can be secured.

The absorption coefficient α of the substrate 10 preferably satisfies the following equation (2)′ or equation (2)″.

0.15λ³≤α≤3λ³ (2)′

0.15λ³≤α≤1.2λ³ (2)

Thereby, better crystallinity of the substrate 10 can be secured while enabling stable heating of the substrate 10.

Further, in the present embodiment, for example, Δα (cm⁻¹) satisfies equation (3) in the wavelength range of at least 1 μm or more and 3.3 μm or less.

Δα≤1.0 (3)

(wherein, a difference between a maximum value and a minimum value of the absorption coefficient α in the main surface of the substrate 10 is Δα (the difference obtained by subtracting the minimum value from the maximum value, hereafter also referred to as “in-plane absorption coefficient difference of the substrate 10”))

In a case of Δα>1.0, there is a possibility that a heating efficiency by irradiation of the infrared rays becomes non-uniform in the main surface of the substrate 10. In contrast, by satisfying Δα≤1.0, the heating efficiency by irradiation of the infrared rays can be uniform in the main surface of the substrate 10.

It is preferable that Δα satisfies equation (3)′.

Δα≤0.5 (3)′

By satisfying Δα≤0.5, the heating efficiency by irradiation of the infrared rays can be stably uniform in the main surface of the substrate 10.

The definitions of equations (2) and (3) regarding the above absorption coefficient α and Δα can be replaced, for example, with definitions at a wavelength of 2 μm.

Namely, in the present embodiment, for example, the absorption coefficient of the substrate 10 at a wavelength of 2 μm is 1.2 cm⁻¹ or more and 48 cm⁻¹ or less. The absorption coefficient of the substrate 10 at a wavelength of 2 μm is preferably 1.2 cm⁻¹ or more and 24 cm⁻¹ or less, and more preferably 1.2 cm⁻¹ or more and 9.6 cm⁻¹ or less.

Further, in the present embodiment, for example, the difference between the maximum value and the minimum value of the absorption coefficient in the main surface of the substrate 10 at a wavelength of 2 μm is within 1.0 cm⁻¹, preferably within 0.5 cm⁻¹.

An upper limit value of the in-plane absorption coefficient difference of the substrate 10 has been described. A lower limit value of the in-plane absorption coefficient difference of the substrate 10 is preferably zero, because the smaller the better. Even if the in-plane absorption coefficient difference of the substrate 10 is 0.01 cm⁻¹, effects of the present embodiment can be sufficiently obtained.

Here, a requirement for the absorption coefficient of the substrate 10 was defined at a wavelength of 2 which corresponds to a peak wavelength of the infrared rays when the temperature is about 1200° C. However, the effect obtained by satisfying the above requirements for the absorption coefficient of the substrate 10 is not limited to a case of setting the temperature to about 1200° C. This is because a spectrum of the infrared rays emitted from the heating source has a predetermined wavelength width in accordance with Stefan-Boltzmann law, and has a component with a wavelength of 2 even if the temperature is not 1200° C. Therefore, if the absorption coefficient of the substrate 10 satisfies the above requirement at a wavelength of 2 μm corresponding to the temperature of 1200° C., the absorption coefficient of the substrate 10 and the difference between the maximum value and the minimum value of the absorption coefficient in the main surface of the substrate 10 fall within a predetermined range, even at wavelengths where the temperature corresponds to other than 1200° C. Thereby, the substrate 10 can be stably heated, and the heating efficiency for the substrate 10 can be uniform in the main surface, even if the temperature is not 1200° C.

The above-described FIG. 4 is the result of measuring the absorption coefficient of GaN crystal at room temperature (27° C.). Therefore, when considering the absorption coefficient of the substrate 10 under a predetermined temperature condition in the step of heating the substrate 10, it is necessary to consider how does the free carrier absorption of GaN crystal under the predetermined temperature condition change relative to the free carrier absorption of GaN crystal under a temperature condition of room temperature.

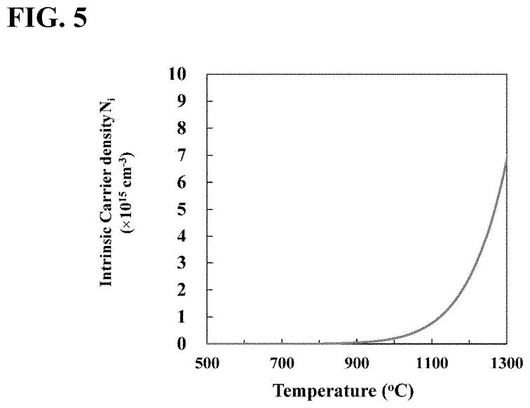

FIG. 5 is a view illustrating an intrinsic carrier density (an intrinsic carrier concentration) with respect to a temperature of GaN crystal. As illustrated in FIG. 5, in GaN crystal constituting the substrate 10, the higher the temperature, the higher an intrinsic carrier concentration Nᵢ that is thermally excited between bands (between a valence band and a conduction band). However, even if the temperature of GaN crystal is around 1300° C., the intrinsic carrier concentration Nᵢ that is thermally excited between the bands of GaN crystal is less than 7×10¹⁵ cm⁻³, and is sufficiently lower than the free carrier concentration (for example, 1×10¹⁷ cm⁻³) generated in GaN crystal by doping with the n-type impurities. Namely, it can be said that the free carrier concentration in GaN crystal falls in a so-called extrinsic region in which the free carrier concentration is determined by doping with the n-type impurities under a temperature condition where the temperature of GaN crystal is less than 1300° C.

Namely, in the present embodiment, the concentration of the intrinsic carriers thermally excited between the bands of the substrate 10 under temperature conditions (under temperature conditions of room temperature (27° C.) or more and 1250° C. or less) in the later-described manufacturing steps of at least the semiconductor laminate 1 and the semiconductor device 2, is lower (for example, 1/10 times or less) than the concentration of the free electrons generated in the substrate 10 by doping with the n-type impurities under the temperature condition of room temperature. Therefore it can be considered that the free carrier concentration in the substrate 10 under the predetermined temperature condition in the step of heating the substrate 10 is approximately equal to the free carrier concentration in the substrate 10 under the temperature condition of room temperature, and it can be considered that the free carrier absorption under the predetermined temperature condition is approximately equal to the free carrier absorption at room temperature. Namely, as described above, when the infrared absorption coefficient of the substrate 10 satisfies the above predetermined requirements at room temperature, it can be considered that the infrared absorption coefficient of the substrate substantially maintains the above predetermined requirements under the predetermined temperature condition as well.

Further, in the substrate 10 of the present embodiment, the absorption coefficient α in the wavelength range of at least 1 μm or more and 3.3 μm or less is approximately expressed by equation (1). Therefore, the absorption coefficient α of the substrate 10 has a substantially proportional relationship to the free electron concentration Nₑ at a predetermined wavelength λ.

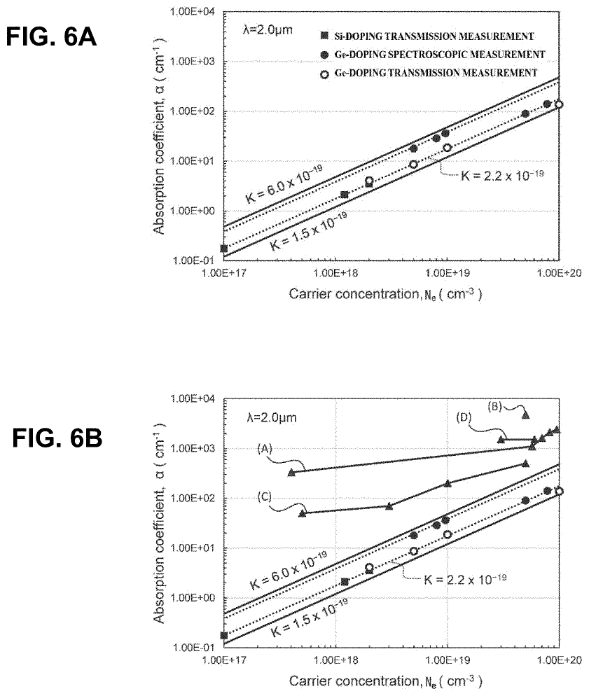

FIG. 6A is a view illustrating a relationship between the absorption coefficient at a wavelength of 2 μm and the free electron concentration in GaN crystal manufactured by the manufacturing method according to the present embodiment. In FIG. 6A, a lower solid line (α=1.2×10⁻¹⁸ n) is a function obtained by substituting K=1.5×10⁻¹⁹ and λ=2.0 into equation (1), and an upper solid line (α=4.8×10⁻¹⁸ n) is a function obtained by substituting K=6.0×10⁻¹⁹ and λ=2.0 into equation (1). FIG. 6A illustrates not only GaN crystal doped with Si, but also GaN crystal doped with Ge. FIG. 6A also illustrates the result of measuring the absorption coefficient by a transmission measurement and the result of measuring the absorption coefficient by a spectroscopic ellipsometry method. As illustrated in FIG. 6A, the absorption coefficient α of GaN crystal manufactured by the later-described manufacturing method has a substantially proportional relationship to the free electron concentration Nₑ. Here, the wavelength λ is 2.0 μm. Further, the actual measured value of the absorption coefficient α of GaN crystal manufactured by the later-described manufacturing method can be fitted with high accuracy by the function of equation (1), within a range of 1.5×10⁻¹⁹≤K≤6.0×10⁻¹⁹. GaN crystal manufactured by the later-described manufacturing method has high purity (that is, low impurity concentration) and good thermophysical property and good electrical property. Therefore, the actual measured value of the absorption coefficient α can be fitted with high accuracy in many cases by the function of equation (1) when K=2.2×10⁻¹⁹, i.e., by α=1.8×10⁻¹⁸ n.

In the present embodiment, the free electron concentration Nₑ in the substrate 10 satisfies the following predetermined requirements, based on the fact that the absorption coefficient α of the above substrate 10 is proportional to the free electron concentration Nₑ.

In the present embodiment, for example, the free electron concentration Nₑ in the substrate 10 is 1.0×10¹⁸ cm⁻³ or more and 1.0×10¹⁹ cm⁻³ or less. Thereby, from equation (1), the absorption coefficient of the substrate 10 at a wavelength of 2 μm can be 1.2 cm⁻¹ or more and 48 cm⁻¹ or less. The free electron concentration Nₑ in the substrate 10 is preferably 1.0×10¹⁸ cm⁻³ or more and 5.0×10¹⁸ cm⁻³ or less, and more preferably 1.0×10¹⁸ cm⁻³ or more and 2.0×10¹⁸ cm⁻³ or less. Thereby, the absorption coefficient of the substrate 10 at a wavelength of 2 μm can be preferably 1.2 cm⁻¹ or more and 24 cm⁻¹ or less, and more preferably 1.2 cm⁻¹ or more and 9.6 cm⁻¹ or less.

Further, the following equation (4) can be obtained by differentiating equation (1).

Δα=8KΔNₑ (4)

(wherein, as described above, the difference between the maximum value and the minimum value of the absorption coefficient α in the main surface of the substrate 10 is Δα, a difference between a maximum value and a minimum value of the free electron concentration Nₑ in the main surface of the substrate 10 is ΔNₑ, and the wavelength λ is 2.0 μm)

In the present embodiment, for example, the difference ΔNₑ between the maximum value and the minimum value of the free electron concentration Nₑ in the main surface of the substrate 10 is within 8.3×10¹⁷ cm⁻³, preferably within 4.2×10¹⁷ cm⁻³. Thereby, from equation (4), the difference Δα between the maximum value and the minimum value of the absorption coefficient at a wavelength of 2 μm can be within 1.0 cm⁻¹, preferably within 0.5 cm⁻¹.

An upper limit value of ΔNₑ has been described. A lower limit value of ΔNₑ is preferably zero, because the smaller the better. Even if ΔNₑ is 8.3×10¹⁵ cm⁻³, the effects of the present embodiment can be sufficiently obtained.

In the present embodiment, the free electron concentration Nₑ in the substrate 10 is equal to the concentration of the n-type impurities in the substrate 10, and the concentration of the n-type impurities in the substrate 10 satisfies the following predetermined requirements.

In the present embodiment, for example, the concentration of the n-type impurities in the substrate 10 is 1.0×10¹⁸ at·cm⁻³ or more and 1.0×10¹⁹ at·cm⁻³ or less. Thereby, the free electron concentration Nₑ in the substrate 10 can be 1.0×10¹⁸ cm⁻³ or more and 1.0×10¹⁹ cm⁻³ or less. The concentration of the n-type impurities in the substrate 10 is preferably 1.0×10¹⁸ at·cm⁻³ or more and 5.0×10¹⁸ at·cm⁻³ or less, and more preferably 1.0×10¹⁸ at·cm⁻³ or more and 2.0×10¹⁸ at·cm⁻³ or less. Thereby, the free electron concentration Nₑ in the substrate 10 can be preferably 1.0×10¹⁸ cm⁻³ or more and 5.0×10¹⁸ cm⁻³ or less, and more preferably 1.0×10¹⁸ cm⁻³ or more and 2.0×10¹⁸ cm⁻³ or less.

Further, in the present embodiment, for example, a difference between a maximum value and a minimum value of the concentration of the n-type impurities in the main surface of the substrate 10 (hereafter, also referred to as in-plane concentration difference of the n-type impurities) is within 8.3×10¹⁷ at·cm⁻³, preferably within 4.2×10¹⁷ at·cm⁻³. Thereby, the difference ΔNₑ between the maximum value and the minimum value of the free electron concentration Nₑ in the main surface of the substrate 10 can be equal to the in-plane concentration difference of the n-type impurities, and can be within 8.3×10¹⁷ cm⁻³, preferably within 4.2×10¹⁷ cm⁻³.

An upper limit value of the in-plane concentration difference of the n-type impurities has been described. A lower limit value of the in-plane concentration difference of the n-type impurity is preferably zero, because the smaller the better. Even if the in-plane concentration difference of the n-type impurities is 8.3×10¹⁵ at·cm⁻³, the effects of the present embodiment can be sufficiently obtained.

Further, in the present embodiment, a concentration of each element in the substrate 10 satisfies the following predetermined requirements.

In the present embodiment, among Si, Ge and O used as the n-type impurities, a concentration of O is extremely low, whose control of an amount of addition is relatively difficult, and the concentration of the n-type impurities in the substrate 10 is determined by a total concentration of Si and Ge whose control of an amount of addition is relatively easy.

Namely, the concentration of O in the substrate 10 is negligibly low, for example, 1/10 or less relative to the total concentration of Si and Ge in the substrate 10. Specifically, for example, the concentration of O in the substrate 10 is less than 1×10¹⁷ at·cm⁻³, and meanwhile the total concentration of Si and Ge in the substrate 10 is 1×10¹⁸ at·cm⁻³ or more and 1.0×10¹⁹ at·cm³ or less. Thereby, the concentration of the n-type impurities in the substrate 10 can be controlled by the total concentration of Si and Ge, whose control of the amount of addition is relatively easy. As a result, the free electron concentration Nₑ in the substrate 10 can be controlled with high accuracy so as to be equal to the total concentration of Si and Ge in the substrate 10, and the difference ΔNₑ between the maximum value and the minimum value of the free electron concentration in the main surface of the substrate 10 can be controlled with high accuracy so as to satisfy predetermined requirements.

Further, in the present embodiment, a concentration of impurities other than the n-type impurities in the substrate 10 is negligibly low, for example, 1/10 or less relative to the concentration of the n-type impurities in the substrate 10 (namely, the total concentration of Si and Ge in the substrate 10). Specifically, for example, the concentration of impurities other than the n-type impurities in the substrate 10 is less than 1×10¹⁷ at·cm⁻³. Thereby, an inhibiting factor for the generation of the free electrons from the n-type impurities can be reduced. As a result, the free electron concentration Nₑ in the substrate 10 can be controlled with high accuracy so as to be equal to the concentration of the n-type impurities in the substrate 10, and the difference ΔNₑ between the maximum value and the minimum value of the free electron concentration in the main surface of the substrate 10 can be controlled with high accuracy so as to satisfy predetermined requirements.

The inventor of the present disclosure confirms as follows: since the later-described manufacturing method is adopted, the concentration of each element in the substrate 10 can be stably controlled so as to satisfy the above requirements.

According to the later-described manufacturing method, it is found that each concentration of 0 and carbon (C) in the substrate 10 can be reduced to less than 5×10¹⁵ at·cm⁻³, and further each concentration of iron (Fe), chromium (Cr), boron (B), etc., in the substrate 10 can be reduced to less than 1×10¹⁵ at·cm⁻³. Further, according to this method, it is found that each concentration of elements other than the above elements can also be reduced to concentrations below the lower limit of detection by secondary ion mass spectrometry (SIMS) measurement.

Further, it is estimated that mobility (μ) is higher in the substrate 10 manufactured by the later-described manufacturing method according to the present embodiment than the mobility of a conventional substrate, because the absorption coefficient due to the free carrier absorption in the substrate 10 of the present embodiment is smaller than the absorption coefficient of the conventional substrate. Thereby, even if the free electron concentration in the substrate 10 of the present embodiment is equal to the free electron concentration in the conventional substrate, resistivity (ρ=1/e Nₑμ) of the substrate 10 of the present embodiment is lower than the resistivity of the conventional substrate. Specifically, when the free electron concentration Nₑ in the substrate 10 is 1.0×10¹⁸ cm⁻³ or more and 1.0×10¹⁹ cm⁻³ or less, the resistivity of the substrate 10 is, for example, 2.2 mΩ·cm or more and 17.4 mΩ·cm or less.

(1-ii) Detailed Constitution of the Semiconductor Layer 20

Next, the semiconductor layer 20 constituting the nitride semiconductor laminate (intermediate body) 1 will be described in detail.

The semiconductor layer 20 is formed on the main surface of the substrate 10 by epitaxial growth. The semiconductor layer 20 comprises single crystal of group-III nitride semiconductor. Specifically, the semiconductor layer 20 comprises, for example, single crystal of GaN, similarly to the substrate 10. Further, since the semiconductor layer 20 is epitaxially grown on the substrate 10, a plane orientation of the semiconductor layer 20 is, for example, a (0001) plane (+c plane, Ga-polar plane), or 000-1 plane (−c plane, N-polar plane), similarly to the substrate 10. The same thing as a case of the substrate 10 can be said for the off-angle of GaN crystal constituting the semiconductor layer 20 as well.

In the present embodiment, a surface (main surface) of the semiconductor layer 20 satisfies predetermined requirements for a reflectance in the infrared region. Specifically, the reflectance on the surface of the semiconductor layer 20 is 5% or more and 30% or less in the wavelength range of at least 1 μm or more and 3.3 μm or less. Thereby, in the step of heating the substrate 10 (semiconductor laminate 1), the substrate 10 can be sufficiently irradiated with the infrared rays. As a result, the substrate 10 can be stably heated.

A surface roughness (arithmetic mean roughness Ra) on the surface of the semiconductor layer 20 is, for example, 1 nm or more and 30 nm or less. Thereby, the reflectance on the surface of the semiconductor layer 20 can be 5% or more and 30% or less in the wavelength range of at least 1 μm or more and 3.3 μm or less.

Next, specific constitution of the semiconductor layer 20 according to the present embodiment will be described.

As illustrated in FIG. 1, the semiconductor layer 20 is constituted including, for example, a base n-type semiconductor layer 21 and a drift layer 22.

(Base n-Type Semiconductor Layer)

The base n-type semiconductor layer 21 is provided so as to contact the main surface of the substrate 10, as a buffer layer for succeeding crystallinity of the substrate 10 and stably epitaxially growing the drift layer 22. Further, the base n-type semiconductor layer 21 is constituted as an n-type GaN layer containing the n-type impurities. Examples of the n-type impurities contained in the base n-type semiconductor layer 21 include Si and Ge, similarly to the substrate 10. A concentration of the n-type impurities in the base n-type semiconductor layer 21 is approximately equal to the concentration of the n-type impurities in the substrate 10, and is, for example, 1.0×10¹⁸ at·cm⁻³ or more and 1.0×10¹⁹ at·cm⁻³ or less.

A thickness of the base n-type semiconductor layer 21 is thinner than a thickness of the drift layer 22, and is, for example, 0.1 μm or more and 3 μm or less.

### (Drift Layer)

The drift layer 22 is provided on the base n-type semiconductor layer 21, and is constituted as an n-type GaN layer containing the n-type impurities at a low concentration. Examples of the n-type impurities in the drift layer 22 include Si and Ge, similarly to the n-type impurities in the base n-type semiconductor layer 21.

A concentration of the n-type impurities in the drift layer 22 is lower than each concentration of the n-type impurities in the substrate 10 and the base n-type semiconductor layer 21, and is, for example, 1.0×10¹⁵ at·cm⁻³ or more and 5.0×10¹⁶ at·cm⁻³ or less. Since the concentration of the n-type impurities in the drift layer 22 is 1.0×10¹⁵ at·cm⁻³ or more, on-resistance of the semiconductor device can be reduced. On the other hand, since the concentration of the n-type impurities in the drift layer 22 is 5.0×10¹⁶ at·cm⁻³ or less, a predetermined breakdown voltage of the semiconductor device can be secured.

For example, the drift layer 22 is provided thicker than the base n-type semiconductor layer 21, in order to improve the breakdown voltage of the semiconductor device. Specifically, the thickness of the drift layer 22 is, for example, 3 μm or more and 40 μm or less. Since the thickness of the drift layer 22 is 3 μm or more, the predetermined breakdown voltage of the semiconductor device can be secured. On the other hand, since the thickness of the drift layer 22 is 40 μm or less, the on-resistance of the semiconductor device can be reduced.

(1-iii) Characteristics of Constitution of the Nitride Semiconductor Laminate 1

Next, characteristics of the constitution of the nitride semiconductor laminate 1 in which the semiconductor layer 20 is formed on the substrate 10, will be described.

As described above, both the substrate 10 and the semiconductor layer 20 constituting the nitride semiconductor laminate 1 comprise crystal of group-III nitride semiconductor (specifically, for example, GaN-single crystal). Namely, the semiconductor layer 20 which is a thin film comprising crystal having the same composition as the substrate 10, is formed on the substrate 10 by epitaxial growth. Therefore, the nitride semiconductor laminate 1 corresponds to a laminate obtained by homoepitaxially growing the semiconductor layer 20 on the substrate 10.

Further, the substrate 10 constituting the nitride semiconductor laminate 1 satisfies predetermined requirements for the infrared absorption coefficient. Thereby, the substrate 10 has the free electron concentration (carrier concentration) and the infrared absorption coefficient which are interdependent. The interdependence called here means that there is a special correlation (necessity) between two matters or among three or more matters, for example, when a certain matter occurs, a specific matter always occurs depending on the certain matter.

Specifically, as described above, the infrared absorption coefficient can be approximately expressed as the function of the free carrier concentration and the wavelength. More specifically, as the interdependence in the substrate 10, the absorption coefficient α is approximately expressed by the above-described equation (1) in the wavelength range of at least 1 μm or more and 3 μm or less. Equation (1) is repeated as follows.

α=NₑKλ^{a} (1)

(wherein, the wavelength is λ (μm), the absorption coefficient of the substrate 10 at 27° C. is α (cm⁻¹), the free electron concentration (carrier concentration) in the substrate 10 is Nₑ (cm⁻³), and K and a are constants, satisfying 1.5×10⁻¹⁹≤K≤6.0×10⁻¹⁹, a=3).

The interdependence in the substrate 10 is not limited to the above example, and for example, may include a case where there is a specific correlation such that the absorption coefficient reduces depending on a reduction of the carrier concentration.

In the nitride semiconductor laminate 1 in which the semiconductor layer 20 is formed on the substrate 10, it is very important to manage a film thickness of the semiconductor layer 20 obtained by homoepitaxial growth. For the purpose, a method capable of measuring noncontactly and nondestructively the film thickness of the semiconductor layer 20, is required. As the method for measuring noncontactly and nondestructively a film thickness obtained by homoepitaxial growth, for example, FT-IR method is known.

However, the nitride semiconductor laminate 1 according to the present embodiment, is a so-called GaN-on-GaN substrate in which the semiconductor layer 20 comprising GaN crystal is homoepitaxially grown on the substrate 10 comprising similar GaN crystal. So far, group-III nitride semiconductor crystal typified by GaN crystal is greatly affected by dislocation scattering, and in particular, there is no difference between the infrared absorption coefficients at a low carrier concentration of 1×10¹⁷ cm⁻³ or less. Therefore, a conventional common general technical knowledge is that it is difficult in principle to measure a film thickness using FT-IR method, in a case of the GaN-on-GaN substrate in which the substrate 10 and the semiconductor layer 20 are comprising GaN crystal having the same composition. More specifically, the conventional common general technical knowledge is that even when a measurement using light in a far infrared region whose wavenumber is for example 500 cm⁻¹ or less, is tried, it is difficult to measure the film thickness using light in the infrared region whose wavenumber is 1000 cm⁻¹ or more (particularly, whose wavenumber is 1500 cm⁻¹ or more), because an absorption amount is very small and the difference between the absorption coefficients hardly becomes apparent.

However, in the present embodiment, as described above, the dislocation density on the main surface of the substrate 10 constituting the nitride semiconductor laminate 1 is low, such that the dislocation density is, for example, 5×10⁶ numbers/cm² or less. In addition, the substrate 10 constituting the nitride semiconductor laminate 1 satisfies predetermined requirements for the infrared absorption coefficient. Therefore, the substrate 10 has the carrier concentration and the infrared absorption coefficient which are interdependent. Further, in the present embodiment, the nitride semiconductor laminate 1 is constituted by using such a substrate 10 and homoepitaxially growing the semiconductor layer 20 on the substrate 10. Since the semiconductor layer 20 is homoepitaxially grown, GaN crystal constituting the semiconductor layer 20 is based on GaN crystal constituting the substrate 10 which is a base of the semiconductor layer 20. Namely, even when the semiconductor layer 20 has a difference in the carrier concentration from the substrate 10, similarly to the substrate 10, the dislocation of the semiconductor layer 20 is low, and the semiconductor layer 20 has a carrier concentration and an infrared absorption coefficient which are interdependent.

Therefore, in the nitride semiconductor laminate 1 of the present embodiment, even in a case of a low carrier concentration of 1×10¹⁷ cm⁻³ or less for example, a difference in the infrared absorption coefficients between the substrate 10 and the semiconductor layer 20 occurs depending on the difference in the carrier concentrations therebetween. As a result, it is possible to measure the film thickness by light in the infrared region whose wavenumber is 1000 cm⁻¹ or more (particularly, whose wavenumber is 1500 cm⁻¹ or more), using FT-IR method. Namely, even when the nitride semiconductor laminate 1 is the GaN-on-GaN substrate, it is possible to measure the film thickness using FT-IR method, overturning the above conventional common general technical knowledge.

More specifically, in the nitride semiconductor laminate 1 of the present embodiment, since the substrate 10 satisfies a relationship approximately expressed by equation (1), the semiconductor layer 20 homoepitaxially grown on the substrate 10 also satisfies a relationship between the carrier concentration Nₑ and the absorption coefficient α. Therefore, even in a case of a low carrier concentration of 1×10¹⁷ cm⁻³ or less for example, a difference in the absorption coefficients α certainly occurs depending on the carrier concentration Nₑ, in the wavelength range of at least 1 μm or more and 3 μm or less (i.e., in a wavenumber range of 3030 cm⁻¹ or more and 10000 cm⁻¹ or less). This is extremely suitable for measuring the film thickness using FT-IR method.

As described above, it is possible to measure the film thickness of the nitride semiconductor laminate 1 which is a GaN-on-GaN substrate, using FT-IR method. In other words, this means that the nitride semiconductor laminate 1 is constituted described later.

As described later in detail, in FT-IR method, a reflection spectrum is obtained by irradiating an analysis object with infrared light. The reflection spectrum called here is obtained by plotting an amount of reflected light during irradiation of the infrared light, with respect to the wavelength (wavenumber). Then, in FT-IR method, a film thickness of the analysis object is measured by analyzing a fringe pattern observed in the obtained reflection spectrum. The fringe pattern called here is a pattern showing a presence of fringe (interference fringe) in which portions having a large amount of light and portions having a small amount of light are generated alternately due to an interference of light, and is a pattern generated according to a change of an optical path length when obtaining the reflection spectrum.

Therefore, in the nitride semiconductor laminate 1 in which the film thickness can be measured using FT-IR method, the fringe pattern is observed in the reflection spectrum obtained by irradiating the semiconductor layer 20 on the substrate 10 with infrared light using FT-IR method. When the fringe pattern is observed in the reflection spectrum, it is possible to measure the film thickness of the semiconductor layer 20, namely, to measure the film thickness using FT-IR method, by analyzing the fringe pattern.

### (2) Manufacturing Method of the Nitride Semiconductor Laminate 1

Next, a procedure of manufacturing the nitride semiconductor laminate 1 having the above constitution will be described. The procedure included the film thickness measurement using FT-IR method. Namely, a manufacturing method of the nitride semiconductor laminate 1 according to the present embodiment will be described.

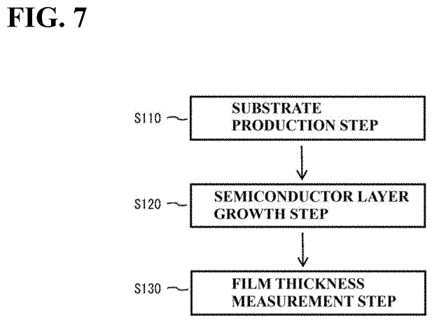

As illustrated in FIG. 7, the manufacturing method of the nitride semiconductor laminate 1 according to the present embodiment includes, at least, a substrate production step (step 110, step is abbreviated as “S”, hereafter), a semiconductor layer growth step (S120), and a film thickness measurement step (S130).

### (2-i) Substrate Production Step

In the substrate production step (S110), the substrate 10 is produced. The substrate 10 is produced using a hydride vapor phase growth apparatus (HYPE apparatus) 200.

### (Constitution of HVPE Apparatus)

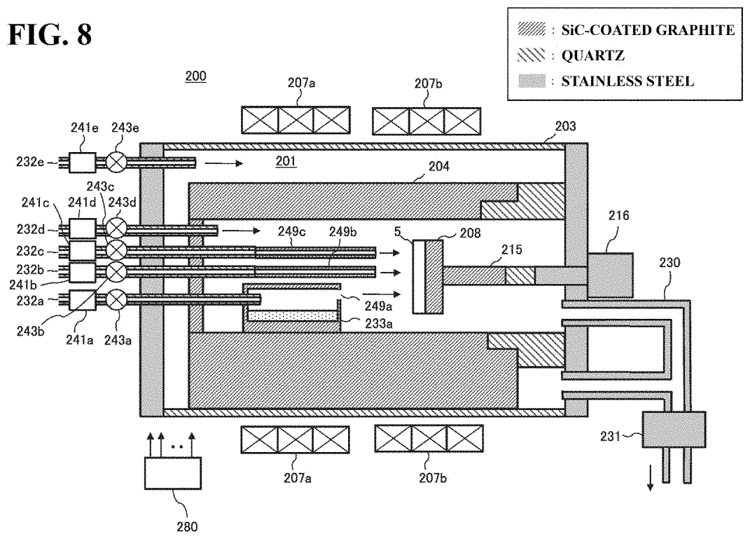

Here, a constitution of the HVPE apparatus 200 used for manufacturing the substrate 10 will be described in detail, with reference to FIG. 8.

The HVPE apparatus 200 includes an airtight container (reaction vessel) 203 in which a film forming chamber (reaction chamber) 201 is constituted. In the film forming chamber 201, an inner cover 204 is provided, and a susceptor 208 as a base on which a seed crystal substrate (hereafter, also referred to as a “seed substrate”) 5 is disposed at a position surrounded by the inner cover 204. The susceptor 208 is connected to a rotation shaft 215 of a rotation mechanism 216, and is constituted to be rotatable according to a drive of the rotation mechanism 216.

A gas supply pipe 232a for supplying hydrogen chloride (HCl) gas into a gas generator 233a, a gas supply pipe 232b for supplying ammonia (NH₃) gas into the inner cover 204, a gas supply pipe 232c for supplying a doping gas described later into the inner cover 204, a gas supply pipe 232d for supplying a mixed gas (N₂/H₂ gas) of nitrogen (N₂) gas and hydrogen (H₂) gas as a purge gas into the inner cover 204, and a gas supply pipe 232e for supplying N₂ gas as a purge gas into the film forming chamber 201, are connected to one end of the airtight container 203. Flow controllers 241a to 241e and valves 243a to 243e are provided, respectively on the gas supply pipes 232a to 232e, sequentially from an upstream side. A gas generator 233a containing Ga melt as a raw material is provided on a downstream of the gas supply pipe 232a. A nozzle 249a is provided to the gas generator 233a, for supplying gallium chloride (GaCl) gas generated by a reaction of HCl gas and Ga melt toward the seed substrate 5 and the like disposed on the susceptor 208. Nozzles 249b and 249c are connected respectively on a downstream of the gas supply pipes 232b and 232c, for supplying various gases supplied from these gas supply pipes toward the seed substrate 5 and the like disposed on the susceptor 208. The nozzles 249a to 249c are disposed to flow the gas in a direction intersecting a surface of the susceptor 208. Doping gas supplied from the nozzle 249c is a mixed gas of a doping source gas and a carrier gas such as N₂/H₂ gas. The doping gas may be flowed together with HCl gas for the purpose of suppressing a thermal decomposition of a halide gas of a doping material. As a doping source gas constituting the doping gas, for example, dichlorosilane (SiH₂Cl₂) gas or silane (SiH₄) gas in the case of silicon (Si) doping, dichlorogermane (GeCl₄) gas or germane (GeH₄) gas in the case of germanium (Ge) doping, may be respectively used. However, the present disclosure is not limited to these gases.

An exhaust pipe 230 is provided at the other end of the airtight container 203, for exhausting inside of the film forming chamber 201. A pump (or blower) 231 is provided on the exhaust pipe 230. Zone heaters 207a and 207b are provided on an outer periphery of the airtight container 203, for heating inside of the gas generator 233a and the seed substrate 5 or the like on the susceptor 208 to a desired temperature for each region. Further, a temperature sensor (not illustrated) is provided in the airtight container 203, for measuring a temperature in the film forming chamber 201.

The constituent members of the HVPE apparatus 200 described above, particularly, the respective members for forming the flow of the various gases, are constituted for example as described later, in order to enable crystal growth with low impurity concentration as described later.

Specifically, as illustrated distinguishably by hatching types in FIG. 8, it is preferable to use a member containing quartz-free and boron-free materials, as a member constituting a high temperature region which is a region heated to a crystal growth temperature (for example, 1000° C. or more) by receiving radiation from the zone heaters 207a and 207b, and which is a region where gas supplied to the seed substrate 5 comes into contact. Specifically, for example, it is preferable to use a member containing silicon carbide (SiC)-coated graphite, as a member constituting the high temperature region. On the other hand, in a relatively low temperature region, it is preferable to constitute a member using high-purity quartz. Namely, in the high temperature region where it is relatively hot and in contact with HCl gas etc., each member is constituted using the SiC-coated graphite without using the high-purity quartz. Specifically, the inner cover 204, susceptor 208, rotating shaft 215, gas generator 233a, nozzles 249a to 249c, etc., are constituted using the SiC-coated graphite. Since a furnace core tube constituting the airtight container 203 can only be quartz, the inner cover 204 is provided in the film forming chamber 201, for surrounding the susceptor 208, the gas generator 233a, and the like. The wall part at the both ends of the airtight container 203, the exhaust pipe 230, etc., may be constituted using metal materials, such as stainless steel.

For example, “Polyakov et al. J. Appl. Phys. 115, 183706 (2014)” discloses that growth at 950° C. enables growth of a low impurity concentration GaN crystal. However, such a low-temperature growth leads to a decrease in the quality of the crystal obtained, and it is not possible to obtain crystal having a good thermal property, electrical property, and the like.

In contrast, according to the above-described HVPE apparatus 200 of the present embodiment, each member is constituted using the SiC-coated graphite in the high temperature region where it is relatively hot and in contact with HCl gas, etc. Thereby, for example, even in a temperature range suitable for the growth of GaN crystal of 1050° C. or more, supply of impurities to a crystal growth portion can be blocked, the impurities being Si, O, C, Fe, Cr, Ni, etc., derived from quartz, stainless steel, and the like. As a result, it is feasible to grow GaN crystal having high purity and excellent properties in thermophysical property and electrical property.

Each member included in the HVPE apparatus 200 is connected to a controller 280 constituted as a computer, and a processing procedure and a processing condition described later are controlled by a program executed on the controller 280.

### (Substrate Production Procedure)

Next, a series of processing in which GaN-single crystal is epitaxially grown on the seed substrate 5 using the above-described HYPE apparatus 200, and thereafter the substrate 10 is obtained by slicing the grown crystal, will be described in detail, with reference to FIG. 8. In the following descriptions, the operation of each part constituting the HVPE apparatus 200 is controlled by the controller 280.

The procedure of producing the substrate 10 using the HVPE apparatus 200 includes a loading step, a crystal growth step, an unloading step, and a slicing step.

### (Loading Step)

Specifically, first, a furnace port of the airtight container 203 is opened, and the seed substrate 5 is placed on the susceptor 208. The seed substrate 5 placed on the susceptor 208 becomes a base (seed) for manufacturing the substrate 10, and is a plate constituted by a single crystal of GaN which is an example of a nitride semiconductor.

In placing the seed substrate 5 on the susceptor 208, the surface of the seed substrate 5 placed on the susceptor 208, namely, the main surface (crystal growth surface, base surface) on the side facing the nozzles 249a to 249c is (0001) plane of GaN crystal, namely, +C plane (Ga-polar plane).

### (Crystal Growth Step)

In this step, after loading of the seed substrate 5 into the film forming chamber 201 is completed, the furnace port is closed, and supply of H₂ gas, or H₂ gas and N₂ gas into the film forming chamber 201 is started while heating and exhausting inside of the film forming chamber 201. Then, supply of HCl gas and NH₃ gas is started from the gas supply pipes 232a and 232b in a state where temperature and pressure inside of the film forming chamber 201 reaches a desired processing temperature and processing pressure, and atmosphere in the film forming chamber 201 becomes a desired atmosphere, and GaCl gas and NH₃ gas are respectively supplied to the surface of the seed substrate 5.

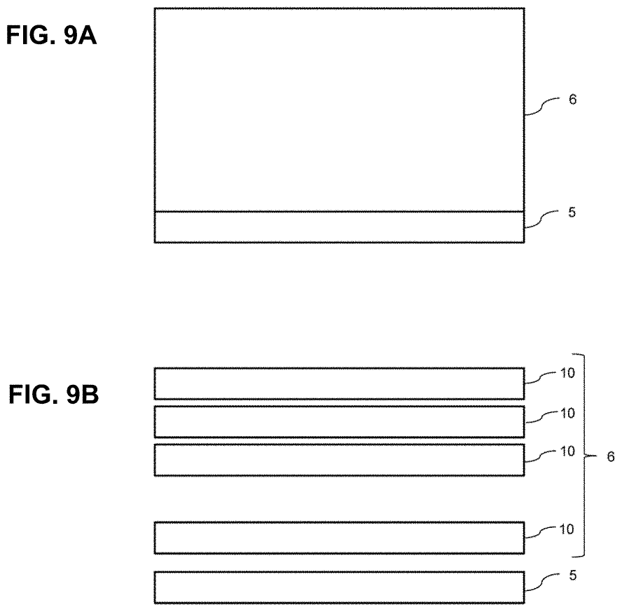

Thereby, as illustrated in a cross-sectional view in FIG. 9A, GaN crystal is epitaxially grown on the surface of the seed substrate 5 in the c-axis direction, and GaN crystal 6 is formed. At this time, by supplying SiH₂Cl₂ gas, it is possible to add Si as the n-type impurity into the GaN crystal 6.

In this step, in order to prevent thermal decomposition of GaN crystals constituting the seed substrate 5, it is preferable to start supply of NH₃ gas into the film forming chamber 201 when the temperature of the seed substrate 5 reaches 500° C. or before that time. Further, in order to improve an in-plane uniformity of a film thickness of the GaN crystal 6, this step is preferably performed with the susceptor 208 rotated.

In this step, temperature of the zone heaters 207a and 207b is preferably set to, for example, to a temperature from 700 to 900° C. in the heater 207a that heats an upstream portion in the film forming chamber 201 including the gas generator 233a, and is preferably set to, for example, to a temperature from 1000 to 1200° C. in the heater 207b that heats a downstream portion in the film forming chamber 201 including the susceptor 208. Thereby, temperature of the susceptor 208 is adjusted to a predetermined temperature of 1000 to 1200° C. In this step, an internal heater (not illustrated) may be used in off state, but temperature control may be performed using the internal heater, as long as the temperature of the susceptor 208 is in the above-described range from 1000 to 1200° C.

Examples of other processing conditions of this step are shown below.

Processing pressure: 0.5 to 2 atm
GaCl gas partial pressure: 0.1 to 20 kPa
NH₃ gas partial pressure/GaCl gas partial pressure: 1 to 100
H₂ gas partial pressure/GaCl gas partial pressure: 0 to 100
SiH₂Cl₂ gas partial pressure: 2.5×10⁻⁵ to 1.3×10⁻³ kPa

Further, when supplying GaCl gas and NH₃ gas to the surface of the seed substrate 5, N₂ gas as a carrier gas may be added from each of the gas supply pipes 232a to 232b. Since N₂ gas is added and blowout flow rate of the gas supplied from the nozzles 249a to 249b is adjusted, a distribution of a supply amount of the source gas on the surface of the seed substrate 5 is appropriately controlled, and a uniform growth rate distribution can be realized over an entire surface. A rare gas such as Ar gas or He gas may be added instead of N₂ gas.

### (Unloading Step)

After the GaN crystal 6 having a desired thickness is grown on the seed substrate 5, supply of HCl gas to the gas generator 233a, supply of H₂ gas into the film forming chamber 201, and heating by the zone heaters 207a and 207b are respectively stopped, while supplying NH₃ gas and N₂ gas into the film forming chamber 201, and exhausting inside of the film forming chamber 201. Then, after the temperature inside of the film forming chamber 201 is lowered to 500° C. or less, supply of NH₃ gas is stopped, and the atmosphere in the film forming chamber 201 is replaced with N₂ gas to return to the atmospheric pressure. Then, the temperature inside of the film forming chamber 201 is lowered to, for example, to 200° C. or less, namely, to a temperature at which a crystal ingot of GaN (seed substrate 5 with the GaN crystal 6 formed on the main surface) can be unloaded from the airtight container 203. Thereafter, the crystal ingot is unloaded from the film forming chamber 201 to outside.

### (Slicing Step)

Thereafter, the unloaded crystal ingot is sliced, for example, in a direction parallel to a growth surface of the GaN crystal 6. Thereby, as illustrated in FIG. 9B, one or more substrates 10 can be obtained. Since various compositions and various physical properties of the substrate 10 are as described above, descriptions thereof are omitted. A slicing process can be performed using, for example, a wire saw or an electric discharge machine, etc. A thickness of the substrate 10 is 250 μm or more, for example, about 400 μm. Thereafter, by performing a predetermined polishing process on the surface (+c plane) of the substrate 10, this surface becomes an epi-ready mirror surface. A back surface (−c plane) of the substrate 10 is a lap-surface or a mirror surface.

Thus, the substrate 10 of the present embodiment constituted as illustrated in FIG. 2, namely, the substrate 10 having the carrier concentration and the infrared absorption coefficient which are interdependent, can be produced.

(2-ii) Semiconductor Layer Growth Step

Next, the semiconductor layer growth step (S120) is performed after producing the substrate 10 in the substrate production step (S110). In the semiconductor layer growth step (S120), the semiconductor layer 20 is formed by homoepitaxially growing GaN crystal on the substrate 10.

The semiconductor layer 20 is formed, for example, using Metal Organic Vapor Phase Epitaxy (MOVPE) method. MOVPE apparatus used for forming the semiconductor layer 20 may be publicly-known apparatus, and a detailed explanation thereof is omitted here.

In forming the semiconductor layer 20, for example, the substrate 10 is irradiated with at least infrared rays, and GaN crystal constituting the semiconductor layer 20 is epitaxially grown on the substrate 10, using MOVPE method.

At this time, since the substrate 10 satisfies the above requirements for the infrared absorption coefficient, the substrate 10 can be stably heated by irradiating the substrate 10 with the infrared rays, and a temperature of the substrate 10 can be controlled with high accuracy. Further, the heating efficiency by irradiation of the infrared rays can be uniform in the main surface of the substrate 10. As a result, crystallinity, thickness, and concentrations of various impurities, etc., of GaN crystal constituting the semiconductor layer 20, can be controlled with high accuracy, and can be uniform in the main surface of the substrate 10.

Specifically, for example, the semiconductor layer 20 of the present embodiment is formed by the following procedure.

First, the substrate 10 is loaded into a process chamber of the MOVPE apparatus (not illustrated).

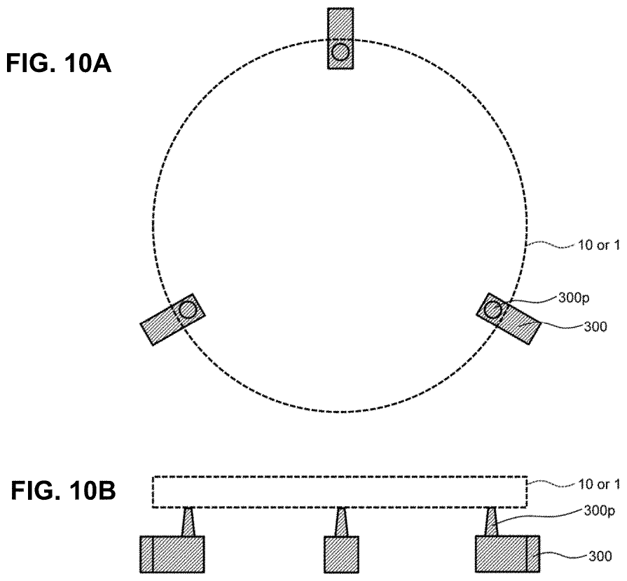

At this time, as illustrated in FIGS. 10A and 10B, the substrate 10 is placed on a holding member 300. The holding member 300 has, for example, three projection portions 300p, and is constituted so that the substrate 10 is held by the three projection portions 300p. Therefore, when the substrate 10 is heated, the substrate 10 can be mainly heated not by a heat transfer to the substrate 10 from the holding member 300 but by irradiation of the infrared rays to the substrate 10. Here, in a case of heating the substrate 10 by the heat transfer from a plate-like holding member (or in a case of heating the substrate 10 by combining the heat transfer), it is difficult to heat uniformly the substrate 10 over the entire surface, depending on a back surface state of the substrate 10 or a surface state of the holding member. Further, there is a possibility that warping in the substrate 10 occurs due to heating of the substrate 10, and a contact condition between the substrate 10 and the holding member gradually changes. Therefore, the heating condition of the substrate 10 is also sometimes ununiform over the entire surface of the substrate 10. In contrast, in the present embodiment, the substrate 10 is mainly heated by irradiating the substrate 10 with the infrared rays using the above-described holding member 300, Thereby, the above problems can be solved, and the substrate 10 can be stably uniformly heated in the main surface of the substrate 10.

In order to reduce an influence due to the heat transfer, it is preferable to select appropriately a shape and a size of the projection portions 300p so that a contact area between the projection portions 300p and the substrate 10 is 5% or less, preferably 3% or less of a surface for supporting the substrate 10.

After the substrate 10 is placed on the holding member 300, hydrogen gas and NH₃ gas (and further N₂ gas) are supplied into the process chamber of the MOVPE apparatus, and the substrate 10 is heated by irradiating the substrate 10 with the infrared rays from a predetermined heating source (for example, lamp heater). After a temperature of the substrate 10 reaches a predetermined growth temperature (for example, 1000° C. or more and 1100° C. or less), for example, trimethylgallium (TMG) as a group-III organic metal source and NH₃ gas as a group-V source are supplied to the substrate 10. At the same time, for example, SiH₄ gas as an n-type impurity source is supplied to the substrate 10. Thereby, the base n-type semiconductor layer 21 as the n-type GaN layer is epitaxially grown on the substrate 10.

Next, the drift layer 22 as the n-type GaN layer containing the n-type impurities at a lower concentration than the concentration of the n-type impurities of the base n-type semiconductor layer 21, is epitaxially grown on the base n-type semiconductor layer 21.

After the growth of the drift layer 22 is completed, supply of group-III organic metal source and heating of the substrate 10 are stopped. Then, after the temperature of the substrate 10 is lowered to 500° C. or less, supply of group-V source is stopped. Then, the atmosphere in the process chamber of the MOVPE apparatus is replaced with N₂ gas to return to the atmospheric pressure, and the temperature inside of the process chamber is lowered to a temperature at which the substrate can be unloaded from the process chamber. Thereafter, the substrate 10 after growth is unloaded from the process chamber.

Thereby, the nitride semiconductor laminate 1 of the present embodiment constituted as illustrated in FIG. 1 is manufactured.

In manufacturing the nitride semiconductor laminate 1, the present embodiment shows, for example, a case of performing the substrate production step (S110) and the semiconductor layer growth step (S120). However, for example, anneal step may be performed, in addition to each of these steps.

In the anneal step, for example, the nitride semiconductor laminate 1 is annealed by irradiating the substrate 10 with at least infrared rays in an inert gas atmosphere, using a predetermined heat treatment apparatus (not illustrated). Thereby, for example, the semiconductor layer 20 constituting the nitride semiconductor laminate 1 can be activated, and crystal damage can be recovered, and the like.

At this time, since the substrate 10 satisfies the above requirements for the infrared absorption coefficient, the substrate 10 can be stably heated by irradiating the substrate 10 with the infrared rays, and the temperature of the substrate 10 can be controlled with high accuracy. Further, the heating efficiency by irradiation of the infrared rays can be uniform in the main surface of the substrate 10. As a result, an activation condition (activation rate, free positive hole concentration) of impurities in the semiconductor layer 20 can be controlled with high accuracy, and can be uniform in the main surface of the substrate 10.

Further, at this time, when the substrate 10 is heated using the holding member 300 illustrated in FIGS. 10A and 10B, the substrate 10 can be mainly heated not by the heat transfer to the substrate 10 from the holding member 300 but by irradiation of the infrared rays to the substrate 10. As a result, the substrate 10 can be stably uniformly heated in the main surface.

(2-iii) Film Thickness Measurement Step

Next, the film thickness measurement step (S130) is performed after the nitride semiconductor laminate 1 is manufactured through the substrate production step (S110) and the semiconductor layer growth step (S120). In the film thickness measurement step (S130), a formation film thickness of the semiconductor layer 20 constituting the nitride semiconductor laminate 1 is measured.

The film thickness of the semiconductor layer 20 can be strictly managed by measuring the film thickness of the semiconductor layer 20 in the film thickness measurement step (S130). Specifically, for example, a quality of the manufactured nitride semiconductor laminate 1 can be determined by measuring the film thickness of the semiconductor layer 20 and comparing its measurement value with a predetermined reference value. Further, for example, it is also conceivable that suitability of various processing conditions when manufacturing the nitride semiconductor laminate 1 is determined, based on the measurement value obtained in the film thickness measurement step (S130).

In the film thickness measurement step (S130) of the present embodiment, the film thickness of the semiconductor layer 20 is measured using FT-IR method capable of measuring noncontactly and nondestructively the film thickness.

A method for measuring the film thickness using FT-IR method will be described in detail hereafter.

### (3) Method for Measuring Film Thickness Using FT-IR Method

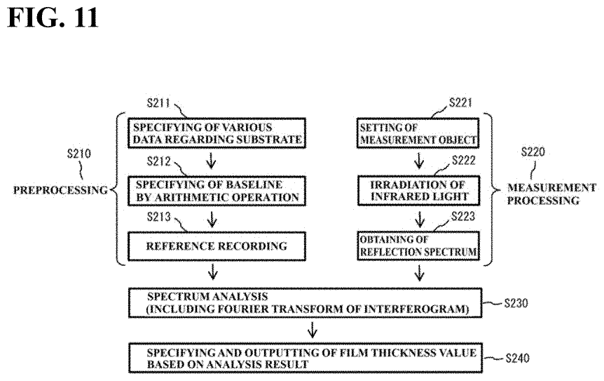

As illustrated in FIG. 11, a method for measuring a film thickness according to the present embodiment includes, at least, a preprocessing step (S210), a measurement step (S220), a spectrum analysis step (S230), and a step of specifying and outputting a film thickness value based on an analysis result (S240). The preprocessing step (S210) includes a step of specifying various data regarding the substrate (S211), a step of specifying a baseline by an arithmetic operation (S212), and a reference recording step (S213). Further, the measurement step (S220) includes a step of setting a measurement object (S221), a step of irradiating with the infrared light (S222), and a step of obtaining the reflection spectrum (S223). Each of these steps will be described hereafter.

### (3-i) Preprocessing Step

In the preprocessing step (S210), processing required in advance for measuring a film thickness using FT-IR method is performed as the preprocessing prior to the measurement step (S220).

### (Modeling of Dielectric Function)

Here, first, modeling of a dielectric function of a measurement object (sample) will be described. The modeling is a premise of the preprocessing step (S210). The dielectric function of sample is required for data analysis. However, in a case that the dielectric function of sample is unknown, modeling of the dielectric function is required.

The measurement object is the intermediate body 1 constituting a Schottky Barrier Diode (SBD). Specifically, the measurement object is the nitride semiconductor laminate 1 in which the semiconductor layer 20 is formed on the substrate 10.

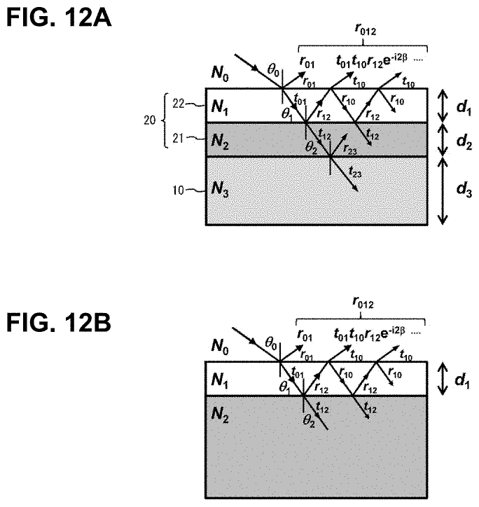

In the nitride semiconductor laminate 1, the semiconductor layer 20 is constituted in a two-layer structure of the base n-type semiconductor layer 21 and the drift layer 22. In the nitride semiconductor laminate 1 having such a laminated structure, a relationship between a reflection and a transmission of light becomes like an optical model illustrated in FIG. 12A.

However, in the nitride semiconductor laminate 1 having such a laminated structure, for example, a reflection of light hardly occurs at an interface of each layer, when light is incident to a material having low refractive index from a material having high refractive index. Therefore, the nitride semiconductor laminate 1 to be the measurement object can be simplified like an optical model illustrated in FIG. 12B instead of an optical model illustrated in FIG. 12A.

Hereafter, as illustrated in FIG. 12B, the nitride semiconductor laminate 1 to be the measurement object is considered by approximation of an optical model of a medium N₀/an epi-layer N₁/a substrate N₂.

In such an optical model, an amplitude reflection coefficient of sample is r₀₁₂ considering multiple reflection on the epi-layer N₁. This amplitude reflection coefficient r₀₁₂ can be obtained by the following equation (5) using Fresnel equation.

$$\begin{matrix}[ Formula 1 ] & \\ {r}_{012} = \frac{{r}_{01} + {r}_{12} exp ( - i 2 β )}{1 + {r}_{01} {r}_{12} exp ( - i 2 β )} & ( 5 )\end{matrix}$$

Phase change B in equation (5) can be obtained by the following equation (6). In equation (6), both θ₁ and θ₀ are an incident angle of light (see FIG. 12). Further, N₁ is a complex refractive index of the epi-layer.

$$\begin{matrix}[ Formula 2 ] & \\ β = \frac{2 π {d}_{1}}{λ} {N}_{1} cos {θ}_{1} = \frac{2 π {d}_{1}}{λ} {( {N}_{1}^{2} - {sin}^{2} {θ}_{0} )}^{0.5} & ( 6 )\end{matrix}$$

Thus, the nitride semiconductor laminate 1 to be the measurement object can be relatively easily analyzed by considering the simplified optical model as illustrated in FIG. 12B and using a virtual substrate approximation considered only a dielectric function of an uppermost layer.

Although a detailed description is omitted here, in analyzing, a first order reflection coefficient r₀₁ from a surface of the epi-layer N₁ and a first order reflection coefficient r₀₂ from the substrate N₂ not having the epi-layer N₁ are also calculated using publicly-known arithmetic expression.

The reflection of light is determined by a complex dielectric constant or a complex refractive index of a substance. Further, light is differentiated into p-polarized light and s-polarized light depending on an electric field direction of light incident on a sample. The p-polarized light and the s-polarized light show different reflections.

Fresnel equation for an amplitude reflection coefficient rₚ of the p-polarized light component is represented by the following equation (7).

$$\begin{matrix}[ Formula 3 ] & \\ {r}_{p} = \frac{{N}_{t i}^{2} cos {θ}_{i} - \sqrt{{N}_{t i}^{2} - {sin}^{2} {θ}_{i}}}{{N}_{t i}^{2} cos {θ}_{i} + \sqrt{{N}_{t i}^{2} - {sin}^{2} {θ}_{i}}} , {N}_{t i} = {N}_{t} / {N}_{i} & ( 7 )\end{matrix}$$

Further, Fresnel equation for an amplitude reflection coefficient rₛ of the s-polarized light component is represented by the following equation (8).

$$\begin{matrix}[ Formula 4 ] & \\ {r}_{s} = \frac{cos {θ}_{i} - \sqrt{{N}_{t i}^{2} - {sin}^{2} {θ}_{i}}}{cos {θ}_{i} + \sqrt{{N}_{t i}^{2} - {sin}^{2} {θ}_{i}}} , {N}_{t i} = {N}_{t} / {N}_{i} & ( 8 )\end{matrix}$$

Here, in equations (7) and (8), θᵢ is an incident angle of light from medium i. Further, Nₜᵢ is a complex refractive index of light incident on medium t from medium i, and is defined by the following equation (9). In equation (9), n is a real part of the complex refractive index, and k is an extinction coefficient. Note that k>0.

[Formula 5]

N≡n−ik (9)

Further, there is a close relationship between a dielectric constant and a refractive index of a substance, a complex dielectric constant c is defined by the following equation (10).

[Formula 6]

N²≡ε (10)

Intensity reflectance R is obtained by squaring an amplitude reflection coefficient r obtained from the above-described Fresnel equation.

Specifically, for example, in a case of vertical incidence (θi=0°), an interface reflectance R with a dielectric (N=n−ik) is represented by the following equation (11), wherein medium N₀ is a vacuum (N=1−i0).

$$\begin{matrix}[ Formula 7 ] & \\ R = {R}_{p} ( = {r}_{p}^{2} ) = {R}_{s} ( = {r}_{s}^{2} ) = \frac{{( n - 1 )}^{2} + {k}^{2}}{{( n + 1 )}^{2} + {k}^{2}} & ( 11 )\end{matrix}$$

On the other hand, for example, in a case of non-vertical incidence (θi≠0°), amplitude reflection coefficients r_{01,p}, r_{01,s}, r_{012,p}, r_{012,s} of the p-polarized light component and the s-polarized light component are calculated respectively, and the interface reflectance R with the dielectric (N=n−ik) is represented by the following equation (12).

$$\begin{matrix}[ Formula 8 ] & \\ R = \frac{{R}_{p} + {R}_{s}}{2} & ( 12 )\end{matrix}$$

The complex dielectric constant c is also defined by the following equation (13), in addition to the above equation (10).

[Formula 9]

ε≡ε₁−iε₂ (13)

It is found that the following equations (14) and (15) are obtained by the above two equations (9) and (13).

[Formula 10]

ε₁=n²−k² (14)

[Formula 11]

ε₂=2nk (15)

Based on each of these equations, the complex refractive index N is given by the following equations (16) and (17), using a value of the complex dielectric constant.

$$\begin{matrix}[ Formula 12 ] & \\ {n}^{2} = \frac{{ɛ}_{1} + \sqrt{{ɛ}_{1}^{2} + {ɛ}_{2}^{2}}}{2} & ( 16 ) \\ [ Formula 13 ] & \\ {k}^{2} = \frac{- {ɛ}_{1} + \sqrt{{ɛ}_{1}^{2} + {ɛ}_{2}^{2}}}{2} & ( 17 )\end{matrix}$$

When the dielectric function model to be applied for the analysis of the optical model is considered, based on a relationship defined by each equation described above, it is conceivable to apply Drude model or Lorentz-Drude model as the dielectric function model, because of the free carrier absorption.

Drude model is a model in which only free carrier absorption is taken into consideration, and the dielectric constant c is obtained by the following equation (18).

$$\begin{matrix}[ Formula 14 ] & \\ ɛ = {ɛ}_{∞} ( 1 - \frac{{ω}_{p}^{2}}{( ω ( ω + i γ ) )} ) & ( 18 )\end{matrix}$$

On the other hand, Lorentz-Drude model is a model in which not only free carrier absorption but also coupling with LO-phonons is taken into consideration, and the dielectric constant c is obtained by the following equation (19).

$$\begin{matrix}[ Formula 15 ] & \\ ɛ = {ɛ}_{∞} ( 1 + \frac{{ω}_{L O}^{2} - {ω}_{T O}^{2}}{{ω}_{T O}^{2} - {ω}^{2} - i ω Γ} - \frac{{ω}_{p}^{2}}{( ω ( ω + i γ ) )} ) & ( 19 )\end{matrix}$$

Here, in the above equation (18) or (19), ε_{∞} is a high frequency dielectric constant. ωₚ, ω_{LO}, and ω_{TO} are, respectively, plasma frequency, LO-phonon frequency, and TO-phonon frequency. Both γ and Γ are damping constants. In equation (19), damping constants of LO-phonon and TO-phonon are assumed to be Γ=Γ_{LO}=Γ_{LO}. Further, the plasma frequency ωₚ is given by the following equation (20), and the damping constant γ is given by the following equation (21).

$$\begin{matrix}[ Formula 16 ] & \\ {ω}_{p}^{2} = \frac{{N}_{e} {e}^{2}}{{ɛ}_{∞} {m}^{*}} & ( 20 ) \\ [ Formula 17 ] & \\ γ = \frac{e}{{m}^{*} μ} & ( 21 )\end{matrix}$$

Here, in the above equation (20) or (21), m* is effective mass of sample. Further, in equation (21), μ is drift mobility.

As described above, in the present embodiment, a measurement object (sample) is simplified like an optical model illustrated in FIG. 12B, and it is determined to apply at least one of Drude model and Lorentz-Drude model as the dielectric function model. Then, processing of each step as described later is performed, using at least one of Drude model and Lorentz-Drude model. It is not particularly limited that which of Drude model and Lorentz-Drude model is applied, or both of them are applied. It may be determined appropriately that which of Drude model and Lorentz-Drude model is applied, or both of them are applied.

### (S211: Step of Specifying Various Data Regarding Substrate)

First, various data required for an arithmetic processing using the dielectric function model are specified, after the dielectric function model is specified as described above. Specifically, various data required for the arithmetic processing using the above equation (18) or (19) are specified.

Various data to be specified here correspond to, for example, to physical property values (characteristic values) regarding each of the substrate N₂ and the epi-layer N₁ constituting the optical model illustrated in FIG. 12B. Here, the substrate N₂ and the epi-layer N₁ are obtained by modeling the substrate 10 and the drift layer 22 in the nitride semiconductor laminate 1. Therefore, various data to be specified can be specified based on physical property values (characteristic values) regarding the substrate 10 and the drift layer 22.

At this time, as described above, the substrate 10 has the low dislocation density, and further satisfies predetermined requirements for the infrared absorption coefficient. Namely, in the substrate 10, the free carrier concentration is controlled with high accuracy, and therefore reliabilities for various physical property values (characteristic values) are high. The same thing can be said for the drift layer 22 epitaxially grown on the substrate 10 as well. Therefore, when various data required for the arithmetic processing using the dielectric function model is specified, based on the physical property values (characteristic values) regarding the substrate 10 and the drift layer 22, the various data are in accordance with a real object (namely, the manufactured nitride semiconductor laminate 1), and has a high reliability.

For example, when the substrate 10 and the semiconductor layer 20 comprise GaN crystal, examples of various data specified here include the following specific example.

Specifically, for example, in a case that Drude model is applied, examples of various data include to be ε_{∞}=5.35, mₑ=0.22, ω_{p_sub}=390.4 cm⁻¹ (μ=320 cm² V⁻¹ s⁻¹), ω_{p_epi}=23.1 cm⁻¹ (μ=1200 cm² V⁻¹ s⁻¹), γ_{sub}=132.6 cm⁻¹, γₑₚᵢ=35.4 cm⁻¹.

Further, for example, in a case that Lorentz-Drude model is applied, examples of various data include to be ε_{∞}=5.35, mₑ=0.22, ω_{LO}=746 cm⁻¹, ω_{TO}=560 cm⁻¹, ω_{p_sub}=390.4 cm⁻¹ (μ=320 cm² V⁻¹ s⁻¹), ω_{p_epi}=23.1 cm⁻¹ (μ=1200 cm² V⁻¹ s⁻¹), Γ=Γ_{LO}=Γ_{TO}=1.27 cm⁻¹, γ_{sub}=132.6 cm⁻¹, γₑₚᵢ=35.4 cm⁻¹.

Various data shown here as specific example correspond to physical property values unique to GaN, or to calculated values by the arithmetic operation using the above-described each equation based on the physical property value. Namely, all of data are values determined uniquely in a case of GaN crystal.

In the present embodiment, when a data calculation is performed by the arithmetic operation, a carrier concentration in an epitaxial layer is obtained in advance by C-V measuring, and the obtained value is used as a constant (fixed) fitting parameter. Even in this case, various data obtained by the data calculation have an extremely high reliability, in consideration that the free carrier concentrations are extremely highly controlled such that the free carrier concentration in the substrate 10 is about 1.0×10¹⁸ to 1.5×10¹⁸ cm⁻³, and the free carrier concentration in the semiconductor layer 20 which is the homoepitaxial layer, is about 2.0×10¹⁸ cm⁻³, for example.

Thus, in the present embodiment, the assumed carrier concentration is obtained, to specify various data. Thereafter, a film thickness is measured using FT-IR method described later. This suggests that in a case that an accuracy of FT-IR measurement itself will be improved in the future, there is a possibility that the carrier concentration and the film thickness are obtained respectively by measuring.

### (S212: Step of Specifying Baseline by Arithmetic Operation)

Next, an arithmetic processing is performed by the dielectric function model, using the specified various data, after various data are specified as described above.

In the arithmetic processing by the dielectric function model, first, the refractive indexes n and the extinction coefficients k for the substrate N₂ and the epi-layer N₁ are obtained.

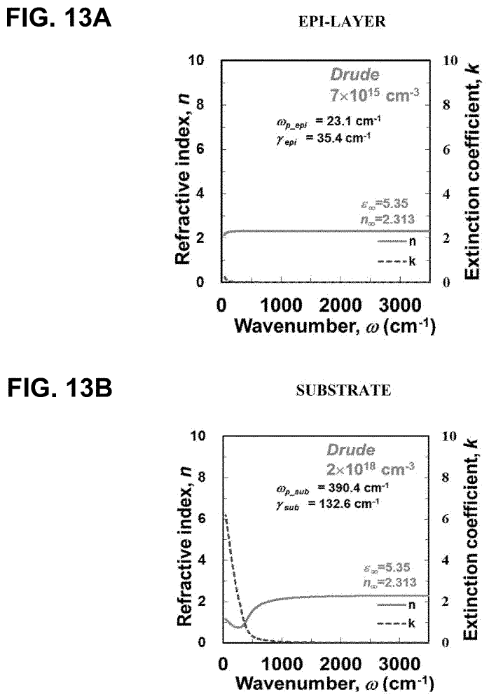

Specifically, for example, in a case that Drude model is applied, the arithmetic processing is performed by the above equation (18), using the specified various data as described above, to obtain the dielectric constant ε. Then, the refractive indexes n and the extinction coefficients k of the substrate N₂ and the epi-layer N₁ are obtained respectively, using the arithmetic (operation) results and the above equations (13) to (17). The arithmetic results are, for example, results as illustrated in FIGS. 13A and 13B.

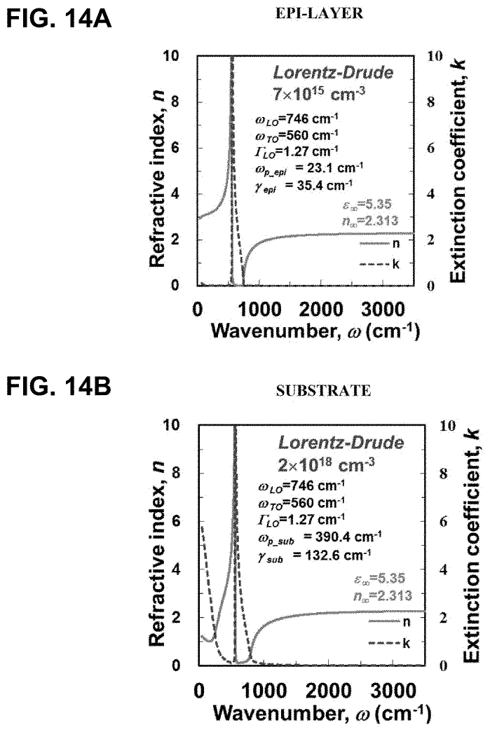

Further, for example, in a case that Lorentz-Drude model is applied, the arithmetic processing is performed by the above equation (19), using the specified various data as described above, to obtain the dielectric constant ε. Then, the refractive indexes n and the extinction coefficients k of the substrate N₂ and the epi-layer N₁ are obtained respectively, using the arithmetic results and the above equations (13) to (17). The arithmetic results are, for example, results as illustrated in FIGS. 14A and 14B.

Next, the reflectance R is calculated using the arithmetic results and the above equation (11) or (12), to obtain the reflection spectrum specified from the arithmetic results of the reflectance, after the refractive indexes n and the extinction coefficients k are obtained.

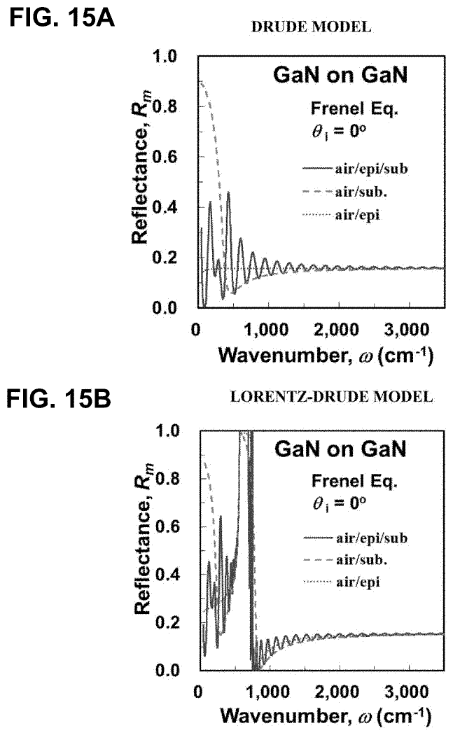

For example, in the case of vertical incidence (θi=0°), the reflection spectrum regarding Drude model is a spectrum as illustrated in FIG. 15A, and the reflection spectrum regarding Lorentz-Drude model is a spectrum as illustrated in FIG. 15B.

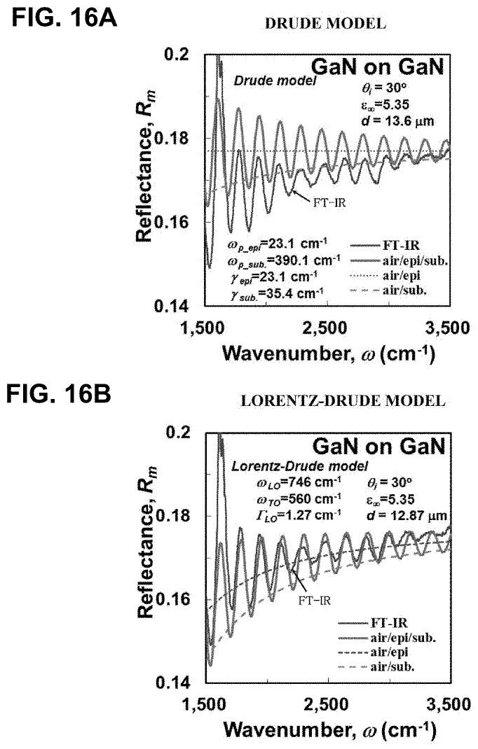

Further, for example, in the case of non-vertical incidence (θi≠0°), further specifically, in a case of θi=30°, the reflection spectrum regarding Drude model is a spectrum as illustrated in FIG. 16A, and the reflection spectrum regarding Lorentz-Drude model is a spectrum as illustrated in FIG. 16B.

As the above-described reflection spectrums, the following respective reflection spectrums can be obtained: a reflection spectrum for the optical model of the medium N₀/the epi-layer N₁/the substrate N₂, based on the reflection coefficient r₀₁₂ (see solid lines in FIG. 15 and FIG. 16), a reflection spectrum for an interface between the medium N₀ and the epi-layer N₁, based on the reflection coefficient r₀₁ (see broken lines in FIG. 15 and FIG. 16), and a reflection spectrum for an interface between the medium N₀ and the substrate N₂, based on the reflection coefficient r₀₂ in the case of not including the epi-layer N₁ (see dotted lines in FIG. 15 and FIG. 16). Among these reflection spectrums, the reflection spectrum for the interface of the substrate N₂ based on the reflection coefficient r₀₂ corresponds to the baseline which is a basis when analyzing the reflection spectrum using FT-IR method.

Namely, in the present embodiment, the reflection spectrum on the single substrate N₂ is obtained by the arithmetic processing such as a simulation, and the reflection spectrum is specified as the baseline used for measuring the film thickness using FT-IR method.

As described above, a specification of such a baseline is performed based on the physical property values (characteristic values) regarding the substrate 10. In the substrate 10, the free carrier concentration is controlled with high accuracy, and therefore various physical property values (characteristic values) has a high reliability. Thus, since various data used for specifying the baseline have a high reliability, in the present embodiment, the baseline can be certainly specified using the arithmetic processing such a simulation.

FIG. 16 also illustrates the reflection spectrum obtained by measuring actually a laminate having the same constitution as the optical model of an analyzed object using FT-IR method (see an arrow “FT-IR” in figure). It is found that when the reflection spectrum is compared with the reflection spectrum for the optical model of the medium N₀/the epi-layer N₁/the substrate N₂, each of the reflection spectrums are approximately expressed (particularly, in a case of Lorentz-Drude model illustrated in FIG. 16B). Also from this fact, it is found that the reflection spectrum obtained by the arithmetic processing in the present embodiment has an extremely high reliability.

Similarly to the film thickness measurement using FT-IR method, the reflection spectrum as described above can be used for calculating the film thickness of the epi-layer N₁ by performing Fourier transform of this reflection spectrum. Specifically, in an example of FIG. 15 or FIG. 16, when the film thickness of the epi-layer N₁ is calculated, the film thickness is as follows: in a case of Drude model, the film thickness dₑₚᵢ=13.6 μm, and in a case of Lorentz-Drude model, the film thickness dₑₚᵢ=12.87 μm. Thus, a difference in the calculation results between each of the models occurs. Conceivably this is because, since there is no LO-phonon member in Drude model, the refractive index n of Drude model is larger than that of Lorentz-Drude model, and the film thickness is calculated thick. Further, as a practical matter, in a case of Drude model, values are changed depending on a wavenumber range used in the film thickness calculation, as is clear from FIG. 16A. In consideration of such a tendency, it may be determined which of Drude model and Lorentz-Drude model is applied, or both of them are applied.

### (S213: Reference Recording Step)

Next, data regarding the specified baseline is recorded as a reference data (basis data) used in the film thickness measurement using FT-IR method, after the baseline is specified as described above.

Recording of the reference data can be performed by storing the reference data in a memory unit included in FT-IR measurement apparatus described later, or by storing the reference data in an external memory device accessible by the FT-IR measurement apparatus.

After recording of the reference data is completed, the preprocessing step (S210) is ended.

(3-ii) Measurement Step

The measurement step (S220) can be performed after the preprocessing step (S210) is ended. In the measurement step (S220), a processing of obtaining the reflection spectrum required for measuring the film thickness of the nitride semiconductor laminate 1 to be a measurement object using FT-IR method, is performed. The processing of obtaining the reflection spectrum is performed using the FT-IR measurement apparatus.

### (Outline of FT-IR Measurement Apparatus)

Here, outline of an FT-IR measurement apparatus 50 will be described simply.

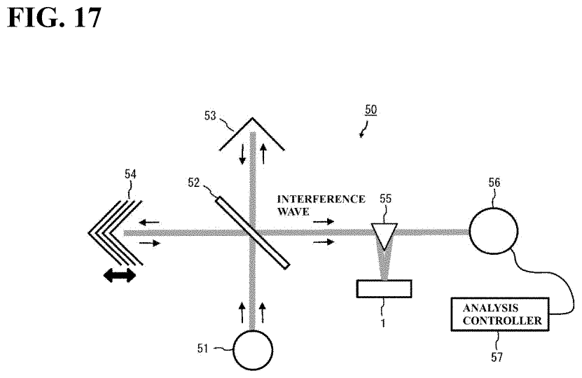

As illustrated in FIG. 17, the FT-IR measurement apparatus 50 is constituted including a light source 51 for emitting light in the infrared region (IR), a half mirror 52, a fixed mirror 53 which is disposed to be fixed, a moving mirror 54 which is movably disposed, a reflection mirror 55, a detector 56 for receiving and detecting light, and an analysis controller 57 configured by a computer or the like connected to the detector 56.

In the FT-IR measurement apparatus 50 having such a constitution, light from the light source 51 is incident obliquely to the half mirror 52, to divide into two luminous fluxes (two beams) of transmitted light and reflected light. The two luminous fluxes are reflected on each of the fixed mirror 53 and the moving mirror 54, and are returned to the half mirror 52, and are combined again, to generate an interference wave (interferogram). At this time, different interference waves are obtained depending on a position of the moving mirror 54 (optical path difference). An optical path of the obtained interference wave is changed by the reflection mirror 55, to irradiate a measurement object (specifically, the nitride semiconductor laminate 1) with the interference wave. Then, an optical path of light reflected on the measurement object (or an optical path of light transmitted through the measurement object) depending on irradiation of the interference wave is changed again by the reflection mirror 55, and thereafter the reflected light (or the transmitted light) is received and detected by the detector 56. Thereafter, the analysis controller 57 analyzes the detected result by the detector 56. Specifically, the analysis controller 57 performs a spectrum analysis using Fourier transform, as described later in detail.

The measurement step (S220) performed using the FT-IR measurement apparatus 50 having such a constitution will be described in detail hereafter.

### (S221: Step of Setting Measurement Object)

In the measurement step (S220), first, the nitride semiconductor laminate 1 to be a measurement object is set at a position irradiated with the interference wave in the FT-IR measurement apparatus 50. A method for setting the nitride semiconductor laminate 1 at the position irradiated with the interference wave is not particularly limited, as long as the method satisfies a specification of the FT-IR measurement apparatus 50. Namely, setting of the nitride semiconductor laminate 1 to be a measurement object may be performed, according to a specification or a constitution, etc., of a sample placing table (not shown) in the FT-IR measurement apparatus 50.

(S222: Step of Irradiating with Infrared Light)

After the nitride semiconductor laminate 1 is set, subsequently, light in the infrared region (IR) is emitted from the light source 51, and the moving mirror 54 is moved appropriately, to generate the interference wave (interferogram). The nitride semiconductor laminate 1 is irradiated with the interference wave. Thereby, the reflected light depending on the interference wave is emitted from the nitride semiconductor laminate 1.

### (S223: Step of Obtaining Reflection Spectrum)

Thereafter, the reflected light emitted from the nitride semiconductor laminate 1 is received and detected by the detector 56. Namely, by receiving and detecting light by the detector 56, and by observing an interference waveforms (interferogram) of the reflected light from the nitride semiconductor laminate 1 as a function of space or time, the reflection spectrum required for measuring the film thickness using FT-IR method is obtained from the nitride semiconductor laminate 1. The reflection spectrum called here is obtained by plotting an amount of the reflected light when irradiating the nitride semiconductor laminate 1 with the interference wave, with respect to the wavelength (wavenumber).

As described above, in the nitride semiconductor laminate 1 to be a measurement object, the dislocation of the substrate 10 is low, and the substrate 10 has the carrier concentration and the infrared absorption coefficient which are interdependent. Further, the same thing can be said for the semiconductor layer 20 homoepitaxially grown on the substrate 10 as well.

Therefore, in a case of the nitride semiconductor laminate 1 of the present embodiment, the reflection spectrum obtained by irradiation of the interference wave reflects an influence of the interference wave. Specifically, a fringe pattern is observed in the reflection spectrum. The fringe pattern is a pattern showing the presence of fringe (interference fringe) in which portions where an amount of light is large and portions where an amount of light is small, are generated alternately depending on an interference of light.

When the fringe pattern is observed in the obtained reflection spectrum, it is possible to measure the film thickness of the nitride semiconductor laminate 1 to be a measurement object, namely, to measure the film thickness using FT-IR method.

The measurement step (S220) is ended, after the reflection spectrum in which the fringe pattern is observed, is obtained from the nitride semiconductor laminate 1 to be a measurement object.

(3-iii) Spectrum Analysis Step

Next, the spectrum analysis step (S230) is performed, after the measurement step (S220) is ended. In the spectrum analysis step (S230), an analysis processing is performed. The analysis processing is a processing of separating mathematically the reflection spectrum obtained in the measurement step (S220) into a wavelength (wavenumber) component by performing Fourier transform while using the reference data recorded in the preprocessing step (S210).

Specifically, in the spectrum analysis step (S230), the following analysis processing is performed. First, the reflection spectrum obtained from the nitride semiconductor laminate 1 is used as a sample spectrum, and the baseline (reflection spectrum) specified by the reference data is used as a background spectrum. Then, each single beam spectrum (SB) of the sample spectrum and background spectrum is obtained by performing Fourier transform of the sample spectrum and background spectrum, to obtain a reflection interference pattern by dividing an intensity of the sample spectrum by an intensity of the background spectrum, based on the following equation (22) for example.

(SB of sample)/(SB of background)×100=reflection interference pattern (22)

Based on the reflection interference pattern thus obtained, it is possible to estimate the film thickness of the semiconductor layer 20 (specifically, for example, the drift layer 22 constituting the semiconductor layer 20) in the nitride semiconductor laminate 1 from a fringe interval of the reflection interference pattern in a near infrared region.

(3-iv) Step of Specifying and Outputting Film Thickness Value Based on Analysis Result

Next, the step of specifying and outputting a film thickness value based on an analysis result (S240) is performed, after the spectrum analysis step (S220) is ended.

In the step of specifying and outputting the film thickness value based on the analysis result (S240), first, a film thickness value of the semiconductor layer 20 (for example, the drift layer 22) in the nitride semiconductor laminate 1 is specified, based on the reflection interference pattern obtained as the analysis result in the spectrum analysis step (S220). Specifically, in the reflection interference pattern obtained in the spectrum analysis step (S220), there are bursts that appear when light is strengthened by the interference. Distance between the bursts corresponds to the optical path difference of each reflection component. Therefore, the film thickness value of the semiconductor layer 20 (for example, the drift layer 22) is specified by dividing the distance between the bursts by a refractive index value of the semiconductor layer 20.

Then, the specified film thickness value is output, after the film thickness value of the semiconductor layer 20 is specified. The film thickness value can be output, for example, using a display unit (not illustrated) included in the FT-IR measurement apparatus 50, or a printer (not illustrated) connected to the FT-IR measurement apparatus 50, etc.

Since the film thickness value is output in this way, user of the FT-IR measurement apparatus 50 referring the output result can be recognized a measurement result of the film thickness of the semiconductor layer 20 in the nitride semiconductor laminate 1. Namely, the film thickness of the semiconductor layer 20 in the nitride semiconductor laminate 1 can be measured using FT-IR method.

### (4) Effect Obtained by the Present Embodiment

According to the present embodiment, one or more of the following effects can be obtained.

(a) In the present embodiment, the nitride semiconductor laminate 1 is constituted by homoepitaxially growing the semiconductor layer 20 on the substrate 10, using the substrate 10 having the carrier concentration and the infrared absorption coefficient which are interdependent. Therefore, in the nitride semiconductor laminate 1, the difference in the infrared absorption coefficients occurs depending on the difference of the carrier concentrations between the substrate 10 and the semiconductor layer 20. As a result, it is possible to measure the film thickness using FT-IR method.

More specifically, in the present embodiment, the dislocation density of the substrate 10 is low, such that the dislocation density is, for example, 5×10⁶ numbers/cm² or less. In addition, the substrate 10 satisfies predetermined requirements for the infrared absorption coefficient. Therefore, the substrate 10 has the carrier concentration and the infrared absorption coefficient which are interdependent. Further, since the semiconductor layer 20 is homoepitaxially grown on the substrate 10, GaN crystal constituting the semiconductor layer 20 is based on GaN crystal constituting the substrate 10. Namely, even in a case that there is a difference in the carrier concentration between the semiconductor layer 20 and the substrate 10, similarly to the substrate 10, the dislocation of the semiconductor layer 20 is low, and the semiconductor layer 20 has the carrier concentration and the infrared absorption coefficient which are interdependent.

Therefore, in the nitride semiconductor laminate 1 of the present embodiment, even in a case of a low carrier concentration of 1×10¹⁷ cm⁻³ or less for example, the difference in the infrared absorption coefficients occurs depending on the difference of the carrier concentrations between the substrate 10 and the semiconductor layer 20. As a result, it is possible to measure the film thickness using FT-IR method.

As described above, according to the present embodiment, it is possible to measure noncontactly and nondestructively the film thickness of the semiconductor layer 20 which is a homoepitaxial film comprising group-III nitride semiconductor crystal, using FT-IR method, because the difference in the IR absorption coefficient occurs depending on the carrier concentration, even in a case of a low carrier concentration of 1×10¹⁷ cm⁻³ or less for example. Therefore, the present embodiment is extremely useful for managing the film thickness of the semiconductor layer 20, and it is feasible to improve a property and a reliability, etc., of a semiconductor device constituted using the nitride semiconductor laminate 1, through the management of the film thickness of the semiconductor layer 20.

(b) Particularly, as described in the present embodiment, the semiconductor layer 20 homoepitaxially grown on the substrate 10 also certainly satisfies the relationship between the carrier concentration Nₑ and the absorption coefficient α, as long as the substrate 10 satisfies the relationship approximately expressed by the above equation (1), namely as long as the interdependence in the substrate 10 is defined by the above equation (1). Therefore, even in a case of a low carrier concentration of 1×10¹⁷ cm⁻³ or less for example, the difference in the absorption coefficients α certainly occurs depending on the carrier concentration Nₑ, in the wavelength range of at least 1 μm or more and 3.3 μm or less. This is extremely suitable for measuring the film thickness using FT-IR method.

The substrate 10 satisfies the relationship approximately expressed by the above equation (1). This is because the substrate 10 is in a state where crystal strain is small and almost no impurities other than 0 and the n-type impurities (for example, impurities, etc., for compensating n-type impurities) are contained. Thereby, in the substrate 10 of the present embodiment, the absorption coefficient α in the wavelength range of at least 1 μm or more and 3.3 μm or less is approximately expressed by equation (1) (α=NₑKλ^{a}) using a predetermined constant K and constant a.

For your reference, in GaN crystal manufactured by a conventional manufacturing method, it is difficult to approximately express the absorption coefficient α by the above equation (1) with high accuracy using the above-defined constant K and constant a.

Here, FIG. 6B is a view for comparing the relationship of the absorption coefficient at a wavelength of 2 μm with respect to the free electron concentration. FIG. 6B illustrates not only the absorption coefficient of GaN crystal manufactured by the manufacturing method of the present embodiment, but also the absorption coefficients of GaN crystal described in the papers (A) to (D).
Paper (A): A. S. Barker Physical Review B 7 (1973) p 743 FIG. 8
Paper (B): P. Perlin, Physical Review Letter 75 (1995) p 296 FIG. 1. Estimated from 0.3 GPa curve.
Paper (C): G. Bentoumi, Material Science Engineering B50 (1997) p 142-147, FIG. 1
Paper (D): S. Porowski, J. Crystal Growth 189-190 (1998) p. 153-158 FIG. 3. However, T=12K

As illustrated in FIG. 6B, the absorption coefficients α of the conventional GaN crystal described in the papers (A) to (D) were larger than the absorption coefficient α of GaN crystal manufactured by the manufacturing method of the present embodiment. Further, slopes of the absorption coefficients α of the conventional GaN crystal were different from a slope of the absorption coefficient α of GaN crystal manufactured by the manufacturing method of the present embodiment. In the papers (A) and (C), it was also seen that the slopes of the absorption coefficients α changed as the free electron concentration Nₑ increased. Therefore, in the conventional GaN crystal described in the papers (A) to (D), it has been difficult to approximately express the absorption coefficient α by the above equation (1) with high accuracy using the above-defined constant K and constant a. Specifically, for example, there is a possibility that the constant K is higher than the above-defined range, or the constant a is a value other than 3.

This is considered to be due to the following reasons. It is considered that a large crystal strain occurred in the conventional GaN crystal due to the manufacturing method. When the crystal strain occurs in GaN crystal, dislocations increase in GaN crystal. Therefore, in the conventional GaN crystal, it is considered that a dislocation scattering occurred and the absorption coefficient α was increased or varied due to the dislocation scattering. Or, in GaN crystal manufactured by the conventional manufacturing method, it is considered that a concentration of O that was mixed unintentionally was high. When O is mixed at a high concentration in GaN crystal, lattice constants a and c of GaN crystal increase (Reference: Chris G. Van de Walle, Physical Review B vol. 68, 165209 (2003)). Therefore, it is considered that in the conventional GaN crystal, a local lattice mismatch occurs between a portion contaminated by O and a portion having relative high purity, and the crystal strain occurs in GaN crystal. As a result, in the conventional GaN crystal, it is considered that the absorption coefficient α increases or varies. Or, it is considered that in GaN crystal manufactured by the conventional manufacturing method, p-type compensation impurity for compensating n-type impurity is mixed unintentionally and a concentration of the compensation impurity is high. If the concentration of the compensation impurity is high, a high concentration of the n-type impurities is required in order to obtain a predetermined free electron concentration. Therefore, in the conventional GaN crystal, it is considered that a total impurity concentration containing the compensation impurity and the n-type impurity is increased, and the crystal strain is increased. As a result, in the conventional GaN crystal, it is considered that the absorption coefficient α increases or varies. In a GaN free-standing substrate actually containing 0 and having a lattice strain, it has been confirmed that the absorption coefficient α is high (low mobility) compared to the substrate 10 of the present embodiment having the same free electron concentration.

For this reason, in the conventional GaN crystal, it has been difficult to approximately express the absorption coefficient α by the above equation (1) with high accuracy using the above-defined constant K and constant a. Namely, in the conventional GaN crystal, it is difficult to design the absorption coefficient with high accuracy based on the free electron concentration Nₑ. Therefore, in the substrate comprising the conventional GaN crystal, heating efficiency easily varies depending on the substrate, and it has been difficult to control a substrate temperature, in the step of heating the substrate by irradiating the substrate with at least infrared rays. As a result, there was a possibility that a temperature reproducibility for each substrate would be low.

In contrast, the substrate 10 manufactured by the manufacturing method of the present embodiment is in a state where crystal strain is small and almost no impurities other than O and the n-type impurities are contained. The absorption coefficient of the substrate 10 of the present embodiment is less affected by scattering due to crystal strain (dislocation scattering) and mainly depends on ionized impurity scattering. Thereby, variation of the absorption coefficient α of the substrate 10 can be reduced, and the absorption coefficient α of the substrate 10 can be approximately expressed by the above equation (1) using the predetermined constant K and constant a. Since the absorption coefficient α of the substrate 10 can be approximately expressed by the above equation (1), the absorption coefficient of the substrate 10 can be designed with high accuracy based on the free electron concentration Nₑ generated by doping the substrate 10 with the n-type impurities. Since the absorption coefficient of the substrate 10 can be designed with high accuracy based on the free electron concentration Nₑ, the heating condition can be easily set, and the temperature of the substrate 10 can be controlled with high accuracy, in the step of heating the substrate 10 by irradiating the substrate 10 with at least infrared rays. As a result, the temperature reproducibility for each substrate 10 can be improved. Thus, in the present embodiment, it becomes possible to heat the substrate 10 with high accuracy and good reproducibility.

(c) In the present embodiment, in measuring the film thickness using FT-IR method, the dielectric function model for the substrate 10 satisfying the above equation (1) is specified, to obtain the reflection spectrum (baseline) on a single substrate 10 by the arithmetic processing, based on the specified dielectric function model. Then, the obtained reflection spectrum is used as the reference data (basis data). Namely, since the substrate 10 has a low dislocation and a high quality, and a controllability of the relationship between the carrier concentration Nₑ and the absorption coefficient α of the substrate 10 is high (namely, a reliability regarding the carrier concentration Nₑ is high), the reflection spectrum to be the baseline can be obtained by the arithmetic processing (simulation). In measuring the film thickness using FT-IR method, the reflection spectrum is obtained from the dielectric function model and the carrier concentration, to use the calculated value as the reference. Therefore, an actual measurement of the reflection spectrum to be the reference from the single substrate for example, is not required, and it is feasible to improve an efficiency of the film thickness measurement.

(d) In the present embodiment, group-III nitride semiconductor crystal is GaN crystal, and the film thickness of a so-called GaN-on-GaN substrate, is measured using FT-IR method. Namely, according to the present embodiment, it is feasible to measure the film thickness using FT-IR method, even in a case of GaN-on-GaN substrate in which it is conventionally considered that it is difficult in principle to measure the film thickness.

(e) In the nitride semiconductor laminate 1 of the present embodiment, the fringe pattern is observed in the reflection spectrum obtained by irradiating the semiconductor layer 20 on the substrate 10 with the infrared rays using FT-IR method. Thus, when the fringe pattern is observed in the reflection spectrum, it is possible to measure the film thickness of the semiconductor layer 20, namely, to measure the film thickness using FT-IR method, by analyzing the fringe pattern. Therefore, in the nitride semiconductor laminate 1 of the present embodiment, it is possible to measure noncontactly and nondestructively the film thickness using FT-IR method, and it is feasible to improve the property and the reliability, etc., of the semiconductor device constituted using the nitride semiconductor laminate 1, through the film thickness management based on the measurement result.

### Other Embodiments

The embodiments of the present disclosure have been specifically described above. However, the present disclosure is not limited to the above-described embodiment, and various modifications can be made without departing from the scope of the disclosure.

The above-described embodiment mainly shows a case of measuring the film thickness using FT-IR method. However, the present disclosure is not limited thereto. For example, in a case that the nitride semiconductor laminate 1 is constituted using the substrate 10 described in the above-described embodiment, since the extinction coefficient k is relatively large on a side of lower wavenumber than TO-phonon (560 cm⁻¹) because of the free carrier absorption, it is possible to measure the film thickness using not only FT-IR method but also an infrared spectroscopy ellipsometry method. The infrared spectroscopy ellipsometry method is one of optical measurement methods, and is a technique for performing the film thickness measurement and the like, by measuring change of a polarization state due to a light reflection on a sample.

The above-described embodiment shows a case that the substrate 10 and the semiconductor layer 20 respectively comprise GaN. However, the substrate 10 and the semiconductor layer 20 may also be comprised not only GaN, but also crystal of another group-III nitride semiconductor. Examples of another group-III nitride semiconductor include indium nitride (InN), indium gallium nitride (InGaN), and the like. Further, AlN, aluminum gallium nitride (AlGaN), aluminum indium gallium nitride (AlInGaN), etc., may be acceptable. Thus, group-III nitride semiconductor include a semiconductor represented by a composition formula of AlₓIn_{y}Ga_{1-x-y}N (0≤x≤1, 0≤y≤1, 0≤x+y≤1). Namely, the present disclosure can be applied in the same manner to not only GaN-on-GaN substrate, but also, for example, AlN-on-AlN substrate which is constituted by homoepitaxially growing an AlN layer on an AlN substrate. In addition, the present disclosure can be applied in the same manner to a homoepitaxial growth substrate by another group-III nitride semiconductor. In a case of comprising Al-composition, it is also conceivable to measure the film thickness measurement using spectroscopy ellipsometry method.

The above-described embodiment shows a case of manufacturing the substrate 10 using the seed substrate 5 comprising GaN-single crystal. However, the substrate 10 may be manufactured by the following method. For example, a GaN layer provided on a heterogeneous substrate such as a sapphire substrate is used as a base layer, then, a crystal ingot on which the GaN layer is grown thickly through a nanomask or the like is peeled off from the heterogeneous substrate, and a plurality of substrates 10 may be cut out from the crystal ingot.

The above-described embodiment shows a case of forming the semiconductor layer 20 using MOVPE method in the semiconductor layer growth step (S120). However, the semiconductor layer 20 may be formed using another vapor phase growth method such as HVPE method, a liquid phase growth method such as a flux method or an ammonothermal method, etc.

The above-described embodiment shows a case that the semiconductor device constituted using the nitride semiconductor laminate 1 is SBD. However, the semiconductor device may be constituted as another device, as long as the substrate 10 comprising the n-type impurities is used. For example, the semiconductor device may be a light-emitting diode, a laser diode, a junction barrier schottky diode (JBS), a bipolar transistor, etc.

### <Preferable Aspects of the Present Disclosure>

Preferable aspects of the present disclosure will be supplementarily described hereafter.

### (Supplementary Description 1)

According to an aspect of the present disclosure, there is provided a method for measuring a film thickness of a thin film in a nitride semiconductor laminate having the thin film homoepitaxially grown on a substrate comprising group-III nitride semiconductor crystal,

wherein the film thickness of the thin film is measured

using the substrate having a carrier concentration and an infrared absorption coefficient which are interdependent, and

using Fourier Transform Infrared Spectroscopy method or Infrared Spectroscopic Ellipsometry method.

### (Supplementary Description 2)

Preferably, there is provided the method for measuring a film thickness of the supplementary description 1, wherein as the interdependence in the substrate, an absorption coefficient α is approximately expressed by the following equation (1) in a wavelength range of at least 1 μm or more and 3.3 μm or less.

α=NₑKλ^{a} (1)

(wherein, a wavelength is λ (μm), an absorption coefficient of the substrate at 27° C. is α (cm⁻¹), a carrier concentration in the substrate is Nₑ (cm⁻³), and K and a are constants, satisfying 2.0×10⁻¹⁹≤K≤6.0×10⁻¹⁹, a=3)

### (Supplementary Description 3)

Preferably, there is provided the method for measuring a film thickness of the supplementary description 2, including:

specifying a dielectric function model for the substrate satisfying the equation (1), to obtain a reflection spectrum on a single substrate by an arithmetic processing, based on the specified dielectric function model; and

using the obtained reflection spectrum as a reference for measuring a film thickness using Fourier Transform Infrared Spectroscopy method or Infrared Spectroscopic Ellipsometry method.

### (Supplementary Description 4)

Preferably, there is provided the method for measuring a film thickness of any one of the supplementary descriptions 1 to 3, wherein the group-III nitride semiconductor crystal is gallium nitride crystal.

### (Supplementary Description 5)

According to another aspect of the present disclosure, there is provided a method for manufacturing a nitride semiconductor laminate having a thin film homoepitaxially grown on a substrate comprising group-III nitride semiconductor crystal, the method including:

homoepitaxially growing the thin film on the substrate having a carrier concentration and an infrared absorption coefficient which are interdependent; and

measuring a film thickness of the thin film formed on the substrate,

wherein in the measurement of the film thickness, the film thickness of the thin film is measured using Fourier Transform Infrared Spectroscopy method or Infrared Spectroscopic Ellipsometry method.

### (Supplementary Description 6)

According to further another aspect of the present disclosure, there is provided a nitride semiconductor laminate, including:

a substrate comprising group-III nitride semiconductor crystal; and

a thin film homoepitaxially grown on the substrate,

wherein a fringe pattern is observed in a reflection spectrum obtained by irradiating the thin film on the substrate with infrared light using Fourier Transform Infrared Spectroscopy method.

### (Supplementary Description 7)

Preferably, there is provided the nitride semiconductor laminate of the supplementary description 6, wherein the substrate has a carrier concentration and an infrared absorption coefficient which are interdependent.

### (Supplementary Description 8)

Preferably, there is provided the nitride semiconductor laminate of the supplementary description 7, wherein as the interdependence in the substrate, an absorption coefficient α is approximately expressed by the following equation (1) in a wavelength range of at least 1 μm or more and 3.3 μm or less.

α=NₑKλ^{a} (1)

(wherein a wavelength is λ (μm), an absorption coefficient of the substrate at 27° C. is α (cm⁻¹), a carrier concentration in the substrate is Nₑ (cm⁻³), and K and a are constants, and satisfying 2.0×10⁻¹⁹≤K≤6.0×10⁻¹⁹, a=3)

### (Supplementary Description 9)

Preferably, there is provided the nitride semiconductor laminate of any one of the supplementary descriptions 6 to 8, wherein the group-III nitride crystal is gallium nitride crystal.

### DESCRIPTION OF SIGNS AND NUMERALS

1 Nitride semiconductor laminate (Intermediate body)
10 Substrate
20 Semiconductor layer
21 Base n-type semiconductor layer
22 Drift layer

1. A method for measuring a film thickness of a thin film in a nitride semiconductor laminate having the thin film homoepitaxially grown on a substrate comprising group-III nitride semiconductor crystal,
wherein the film thickness of the thin film is measured
using the substrate having a carrier concentration and an infrared absorption coefficient which are interdependent, and
using Fourier Transform Infrared Spectroscopy method or Infrared Spectroscopic Ellipsometry method.

2. The method for measuring a film thickness according to claim 1, wherein as the interdependence in the substrate, an absorption coefficient α is approximately expressed by the following equation (1) in a wavelength range of at least 1 μm or more and 3.3 μm or less.
α=NₑKλ^{a} (1)
(wherein, a wavelength is λ (μm), an absorption coefficient of the substrate at 27° C. is α (cm⁻¹), a carrier concentration in the substrate is Nₑ (cm⁻³), and K and a are constants, satisfying 2.0×10⁻¹⁹≤K≤6.0×10⁻¹⁹, a=3)

3. The method for measuring a film thickness according to claim 2, comprising:
specifying a dielectric function model for the substrate satisfying the equation (1), to obtain a reflection spectrum on a single substrate by an arithmetic processing, based on the specified dielectric function model; and
using the obtained reflection spectrum as a reference for measuring a film thickness using Fourier Transform Infrared Spectroscopy method or Infrared Spectroscopic Ellipsometry method.

4. The method for measuring a film thickness according to claim 1, wherein the group-III nitride semiconductor crystal is gallium nitride crystal.

5. A method for manufacturing a nitride semiconductor laminate having a thin film homoepitaxially grown on a substrate comprising group-III nitride semiconductor crystal, the method comprising:
homoepitaxially growing the thin film on the substrate having a carrier concentration and an infrared absorption coefficient which are interdependent; and
measuring a film thickness of the thin film formed on the substrate,
wherein in the measurement of the film thickness, the film thickness of the thin film is measured using Fourier Transform Infrared Spectroscopy method or Infrared Spectroscopic Ellipsometry method.

6. A nitride semiconductor laminate, comprising:
a substrate comprising group-III nitride semiconductor crystal; and
a thin film homoepitaxially grown on the substrate,
wherein a fringe pattern is observed in a reflection spectrum obtained by irradiating the thin film on the substrate with infrared light using Fourier Transform Infrared Spectroscopy method.

7. The nitride semiconductor laminate according to claim 6, wherein the substrate has a carrier concentration and an infrared absorption coefficient which are interdependent.

8. The nitride semiconductor laminate according to claim 7, wherein as the interdependence in the substrate, an absorption coefficient α is approximately expressed by the following equation (1) in a wavelength range of at least 1 μm or more and 3.3 μm or less.
α=NₑKλ^{a} (1)
(wherein a wavelength is λ (μm), an absorption coefficient of the substrate at 27° C. is α (cm⁻¹), a carrier concentration in the substrate is Nₑ (cm⁻³), and K and a are constants, and satisfying 2.0×10⁻¹⁹≤K≤6.0×10⁻¹⁹, a=3)

9. The nitride semiconductor laminate according to claim 6, wherein the group-III nitride crystal is gallium nitride crystal.

10. The method for measuring a film thickness according to claim 2, wherein the group-III nitride semiconductor crystal is gallium nitride crystal.

11. The method for measuring a film thickness according to claim 3, wherein the group-III nitride semiconductor crystal is gallium nitride crystal.

12. The nitride semiconductor laminate according to claim 7, wherein the group-III nitride crystal is gallium nitride crystal.

13. The nitride semiconductor laminate according to claim 8, wherein the group-III nitride crystal is gallium nitride crystal.
